(19) United States
(12) Patent Application Publication
(10) Pub. No.: US 2023/0261017 A1
(43) Pub. Date: Aug. 17, 2023

(54) IMAGING DEVICE, ELECTRONIC DEVICE, AND MOVING OBJECT

(71) Applicant: Semiconductor Energy Laboratory Co., Ltd., Atsugi-shi, Kanagawa-ken (JP)

(72) Inventors: Hiroki INOUE, Atsugi (JP); Seiichi YONEDA, Isehara (JP); Yusuke NEGORO, Kaizuka (JP); Takayuki IKEDA, Atsugi (JP); Naoto KUSUMOTO, Isehara (JP); Kensuke YOSHIZUMI, Atsugi (JP); Shunpei YAMAZAKI, Setagaya (JP)

(21) Appl. No.: 18/014,207

(22) PCT Filed: Jul. 16, 2021
(86) PCT No.: PCT/IB2021/056422

§ 371 Date: Jan. 3, 2023

(30) Foreign Application Priority Data
Jul. 31, 2020 (JP) 2020-129838

(51) Int. Cl. H01L 27/146

(52) U.S. Cl. CPC H01L 27/14623; H01L 27/14627; H01L 27/14621; H01L 27/14616; H01L 27/1461

(57) ABSTRACT

A highly functional imaging device is provided. A small imaging device is provided. An imaging device or the like capable of high-speed operation is provided. A highly reliable imaging device is provided. The imaging device includes a pixel array, and a light-blocking layer and a transparent conductive layer that are over the pixel array. The light-blocking layer includes a first region overlapping with a first pixel and a second region overlapping with a second pixel. The transparent conductive layer includes a region overlapping with the first region and a region overlapping with the second region. The transparent conductive layer has a light-transmitting property. The transparent conductive layer is electrically connected to the first region and the second region. First light enters the photoelectric conversion device included in the first pixel. Second light enters the photoelectric conversion device included in the second pixel. The imaging device has a function of sensing a focal point in image formation with use of a first electric signal generated by conversion of the first light and a second electric signal generated by conversion of the second light.

### TECHNICAL FIELD

One embodiment of the present invention relates to an imaging device.

Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. More specifically, examples of the technical field of one embodiment of the present invention disclosed in this specification include a semiconductor device, a display device, a liquid crystal display device, a light-emitting device, a lighting device, a power storage device, a memory device, an imaging device, a driving method thereof, and a manufacturing method thereof.

In this specification and the like, a semiconductor device generally means a device that can function by utilizing semiconductor characteristics. A transistor and a semiconductor circuit are embodiments of semiconductor devices. In some cases, a memory device, a display device, an imaging device, or an electronic device includes a semiconductor device.

### BACKGROUND ART

A technique for forming a transistor using an oxide semiconductor thin film formed over a substrate has attracted attention. For example, an imaging device with a structure in which a transistor including an oxide semiconductor and having an extremely low off-state current is used in a pixel circuit is disclosed in Patent Document 1.

Examples of the performance required for the imaging device include a high resolution and a highly accurate auto-focus function (Non-Patent Document 1).

As a focus sensing method, an example using a pupil division phase difference method is disclosed in Patent Document 2.

### REFERENCE

### Patent Document

### [Patent Document 1] Japanese Published Patent Application No. 2011-119711

### [Patent Document 2] Japanese Published Patent Application No. 2012-165070

### Non-Patent Document

[Non-Patent Document 1] T. Okawa et al., “A ½ inch 48M All PDAF CMOS Image Sensor Using 0.8 μm Quad Bayer Coding 2×2 OCL with 1.0 lux Minimum AF Illuminance Level,” IEDM Tech. Dig., pp. 374-377 (2019).

### SUMMARY OF THE INVENTION

### Problems to be Solved by the Invention

An object of one embodiment of the present invention is to provide a highly functional imaging device. Another object is to provide a small imaging device. Another object is to provide an imaging device or the like capable of high-speed operation. Another object is to provide a highly reliable imaging device. Another object is to provide a novel imaging device or the like. Another object is to provide a method for driving the above-described imaging device. Another object is to provide a novel semiconductor device or the like.

Note that the description of these objects does not preclude the existence of other objects. One embodiment of the present invention does not have to achieve all the objects. Other objects are apparent from and can be derived from the description of the specification, the drawings, the claims, and the like.

### Means for Solving the Problems

One embodiment of the present invention is an imaging device including a pixel array that includes n pixels (n is a natural number of 4 or more), and a light-blocking layer and a transparent conductive layer that are positioned over the pixel array. Each of then pixels includes a photoelectric conversion device. The light-blocking layer includes a first region overlapping with a first pixel and a second region overlapping with a second pixel. The transparent conductive layer includes a region overlapping with the first region and a region overlapping with the second region. The transparent conductive layer has a light-transmitting property. The transparent conductive layer is electrically connected to the first region and the second region. First light enters the photoelectric conversion device included in the first pixel. Second light enters the photoelectric conversion device included in the second pixel. The imaging device has a function of performing processing with use of a first electric signal generated by conversion of the first light and a second electric signal generated by conversion of the second light.

In the above structure, the imaging device preferably has a function of sensing a focal point in image formation with use of the first electric signal generated by conversion of the first light and the second electric signal generated by conversion of the second light.

In the above structure, the transparent conductive layer preferably includes a region overlapping with two or more of a third pixel to an n-th pixel.

In the above structure, preferably, the transparent conductive layer includes a plurality of openings in line; each of the plurality of openings overlaps with one or more of the third pixel to the n-th pixel; and the plurality of openings are positioned so as to form a grid shape.

In the above structure, preferably, a microlens array including m microlenses (m is a natural number of (n−1) or less) is included; a first microlens overlaps with the first pixel; a second microlens overlaps with the second pixel; in the case where the first pixel is divided, in a top view, into a third region and a fourth region along a first straight line that passes through a light axis of the first microlens, the first region overlaps with less than 40% of the third region and 70% or more of the fourth region; in the case where the second pixel is divided, in the top view, into a fifth region and a sixth region along a second straight line that passes through a light axis of the second microlens, the second region overlaps with 70% or more of the fifth region and less than 40% of the sixth region; the first straight line is parallel to the second straight line; the direction perpendicular to the first straight line and the second straight line is the x axis in the top view; the fourth region is positioned in a region that has a larger x-coordinate than the third region; and the sixth region is positioned in a region that has a larger x-coordinate than the fifth region.

In the above structure, preferably, a microlens array including m microlenses (m is a natural number of (n−1) or less) is included; a first microlens overlaps with the first pixel, the second pixel, the third pixel, and a fourth pixel; and a second microlens overlaps with a fifth pixel, a sixth pixel, a seventh pixel, and an eighth pixel.

In the above structure, preferably, the light-blocking layer includes a first opening; the first opening overlaps with the fifth pixel, the sixth pixel, the seventh pixel, and the eighth pixel; and the transparent conductive layer includes a region overlapping with the first opening.

In the above structure, preferably, a color filter with any of colors of red, green, and blue is provided over each of the third pixel to the n-th pixel; color filters with the same color are provided over the first pixel, the second pixel, the third pixel, and the fourth pixel; and color filters with the same color are provided over the fifth pixel, the sixth pixel, the seventh pixel, and the eighth pixel.

In the above structure, preferably, each of the n pixels includes a transistor; and the light-blocking layer overlaps with one or more of the transistors included in the third pixel to the n-th pixel.

In the above structure, each of the n pixels preferably includes a transistor including an oxide semiconductor in a channel formation region.

In the above structure, the photoelectric conversion device is preferably a pn-junction diode provided on a silicon substrate.

One embodiment of the present invention is an imaging device including a pixel array that includes two or more pixels, and a liquid crystal element that is positioned over the pixel array. Each of the pixels included in the pixel array includes a photoelectric conversion device. The liquid crystal element includes a first region overlapping with a first pixel and a second region overlapping with a second pixel. First light enters the photoelectric conversion device included in the first pixel. Second light enters the photoelectric conversion device included in the second pixel. The imaging device has a function of sensing a focal point in image formation with use of a first electric signal generated by conversion of the first light and a second electric signal generated by conversion of the second light.

In the above structure, the liquid crystal element preferably has a function of blocking light when the focal point sensing is performed and transmitting light when the focal point sensing is not performed.

Another embodiment of the present invention is an electronic device including the imaging device described in any of the above and a display portion.

Another embodiment of the present invention is a moving object including the imaging device described in any of the above and an integrated circuit having a function of performing image processing.

### Effect of the Invention

With the use of one embodiment of the present invention, a highly functional imaging device can be provided. A small imaging device can be provided. An imaging device or the like capable of high-speed operation can be provided. A highly reliable imaging device can be provided. A novel imaging device or the like can be provided. A method for driving the above-described imaging device can be provided. A novel semiconductor device or the like can be provided.

### BRIEF DESCRIPTION OF THE DRAWINGS

FIG. 1 is a diagram illustrating a pixel.

FIG. 2 is a diagram illustrating a pixel.

FIG. 3A and FIG. 3B are diagrams each illustrating a pixel circuit.

FIG. 4A and FIG. 4B are diagrams each illustrating a layout of a pixel circuit.

FIG. 5A and FIG. 5B are diagrams each illustrating a pixel circuit.

FIG. 6 is a timing chart showing an operation of a pixel.

FIG. 7 is a block diagram illustrating an imaging device.

FIG. 8A and FIG. 8B are diagrams each illustrating a pixel circuit.

FIG. 9 is a block diagram illustrating an imaging device.

FIG. 10 is a diagram illustrating a pixel block 200 and a circuit 201.

FIG. 11A and FIG. 11B are diagrams each illustrating a pixel 100.

FIG. 12A and FIG. 12B are timing charts each showing operations of the pixel block 200 and the circuit 201.

FIG. 13A and FIG. 13B are diagrams each illustrating circuits 301 and a circuit 302.

FIG. 14 is a diagram illustrating memory cells.

FIG. 15A and FIG. 15B are diagrams each illustrating a structure example of a neural network.

FIG. 16A and FIG. 16B are diagrams each illustrating a structure example of a photoelectric conversion device.

FIG. 17 is an example of a cross-sectional view of an imaging device.

FIG. 18A, FIG. 18B, and FIG. 18C are each an example of a cross section of a transistor.

FIG. 19A and FIG. 19B are each an example of a top view of an imaging device.

FIG. 20A and FIG. 20B are each an example of a top view of an imaging device.

FIG. 21A and FIG. 21B are each an example of a top view of an imaging device.

FIG. 22A and FIG. 22B are each an example of a top view of an imaging device.

FIG. 23A and FIG. 23B are each an example of a top view of an imaging device.

FIG. 24A and FIG. 24B are each an example of a top view of an imaging device.

FIG. 25A and FIG. 25B are each an example of a top view of an imaging device.

FIG. 26 is an example of a cross-sectional view of an imaging device.

FIG. 27 is an example of a cross-sectional view of an imaging device.

FIG. 28 is an example of a cross-sectional view of an imaging device.

FIG. 29 is an example of a cross-sectional view of an imaging device.

FIG. 30 is an example of a cross-sectional view of an imaging device.

FIG. 31 is an example of a cross-sectional view of an imaging device.

FIG. 32A, FIG. 32B, FIG. 32C, and FIG. 32D are each an example of a cross section of a transistor.

FIG. 33A to FIG. 33F are perspective views illustrating a package and a module including an imaging device.

FIG. 34A to FIG. 34F are diagrams each illustrating an electronic device.

FIG. 35A and FIG. 35B are diagrams illustrating an automobile.

### MODE FOR CARRYING OUT THE INVENTION

Embodiments are described in detail with reference to the drawings. Note that the present invention is not limited to the following description, and it is readily appreciated by those skilled in the art that modes and details can be modified in various ways without departing from the spirit and the scope of the present invention. Therefore, the present invention should not be construed as being limited to the description of embodiments below. Note that in structures of the invention described below, the same portions or portions having similar functions are denoted by the same reference numerals in different drawings, and the description thereof is not repeated in some cases. The same components are denoted by different hatching patterns in different drawings, or the hatching patterns are omitted in some cases.

Even in the case where a single component is illustrated in a circuit diagram, the component may be composed of a plurality of parts as long as there is no functional inconvenience. For example, in some cases, a plurality of transistors that operate as switches may be connected in series or in parallel. In some cases, capacitors are divided and arranged in a plurality of positions.

One conductor has a plurality of functions such as a wiring, an electrode, and a terminal in some cases; in this specification, a plurality of names are used for the same component in some cases. Even in the case where elements are illustrated in a circuit diagram as if they were directly connected to each other, the elements may actually be connected to each other through one conductor or a plurality of conductors; in this specification, even such a structure is included in direct connection.

### Embodiment 1

In this embodiment, an imaging device of one embodiment of the present invention is described with reference to drawings.

### <Stacked-Layer Structure >

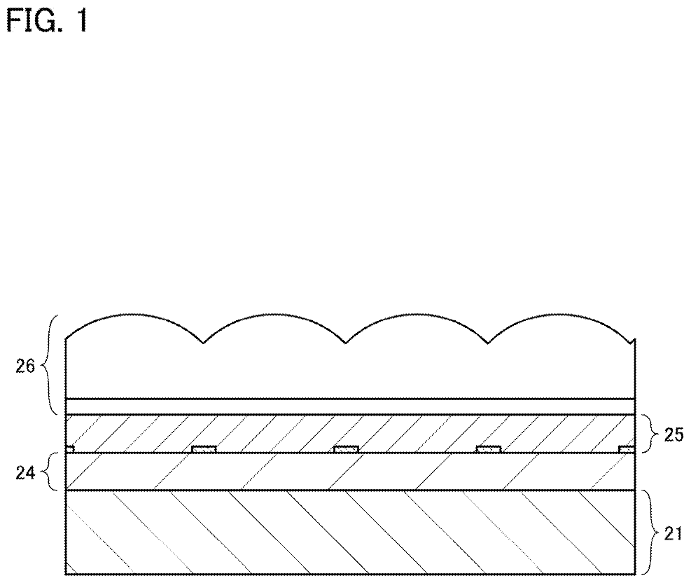

FIG. 1 is a cross-sectional view of a pixel in the imaging device of one embodiment of the present invention. The pixel has a structure in which a layer 21, a layer 24, a layer 25, and a layer 26 are stacked. The layer 21 includes a support substrate and the like. The layer 24 includes a transistor, a photoelectric conversion device, and the like. The layer 25 includes a photoelectric conversion layer and the like. The layer 26 includes a microlens array and the like.

The transistor and the like provided in the layer 24 can constitute a pixel circuit (excluding the photoelectric conversion device), a driver circuit of the pixel circuit, a reading circuit, a memory circuit, an arithmetic circuit, and the like. Note that in the following description, these circuits are collectively referred to as a functional circuit in some cases.

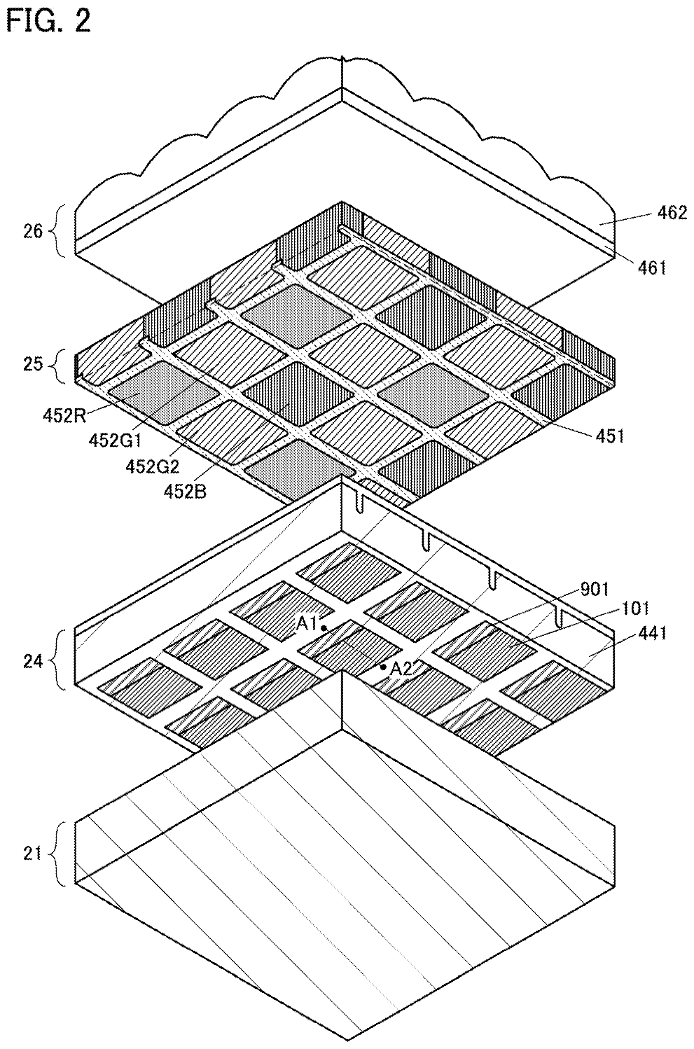

Detailed structures of the respective layers are described with reference to FIG. 2. FIG. 2 illustrates the separated layers of the stacked-layer structure illustrated in FIG. 1. Note that components included in each layer are not limited to components illustrated in FIG. 2, and another component may be included. In a structure in which two layers are in contact with each other, a component such as an insulating layer positioned near the boundary is illustrated as a component of one layer for convenience, but may be a component of the other layer.

### <Layer 21>

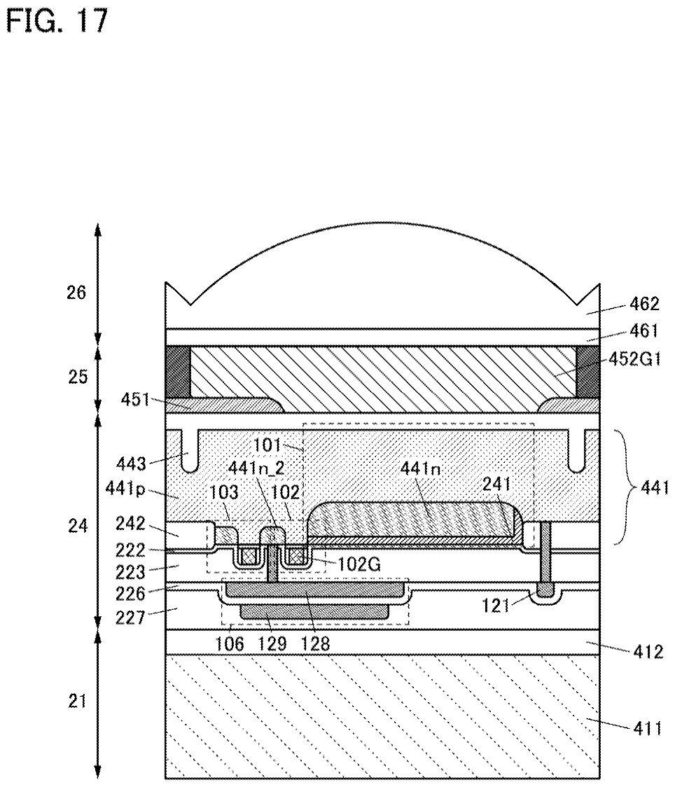

The layer 21 is a support substrate, which preferably has hardness and a flat surface. For example, a semiconductor substrate of silicon or the like, a glass substrate, a ceramic substrate, a metal substrate, or a resin substrate can be used. For example, in the structure illustrated in FIG. 17 described below, the layer 21 includes a substrate 411 and an insulating layer 412 covering the substrate 411. A structure without the layer 21 may also be employed.

### <Layer 24>

The layer 24 includes a photoelectric conversion device 101 and a circuit portion 901, which are provided on a substrate 441. The circuit portion 901 includes, for example, a transistor in which a channel region is formed on the substrate 441. For the substrate 441, silicon, silicon carbide, germanium, silicon germanium, an oxide semiconductor, or the like can be used. As the photoelectric conversion device 101, a photodiode can be used, for example. The photodiode can be a pn-junction photodiode having a first light-receiving plane that is a surface of the substrate 441. Although a region indicating the photoelectric conversion device 101 and a region indicating the circuit portion 901 each have a rectangular shape in FIG. 2, each of the regions can have a freely designed shape. The regions may overlap each other in a region. The regions may include some components in common. For example, one of a source and a drain of a transistor electrically connected to the photoelectric conversion device 101 may also serve as an n-type region or a p-type region of the photoelectric conversion device 101.

### <Layer 25>

The layer 25 is a layer including an optical conversion layer; an example shown here includes color filters 452R, 452G1, 452G2, and 452B corresponding to color imaging. The layer includes a light-blocking layer 451.

The color filter 452R is colored red, the color filter 452G1 and the color filter 452G2 are colored green, and the color filter 452B is colored blue. The color filter 452R, the color filter 452G1, the color filter 452G2, and the color filter 452B are provided in regions overlapping with the corresponding photoelectric conversion devices 101.

The light-blocking layer 451 is provided between the color filters, e.g., in a position overlapping with the boundary therebetween, and can prevent light passing through a color filter from entering an adjacent pixel.

The light-blocking layer 451 preferably includes a region that overlaps with one or more transistors included in the circuit portion 901. More specifically, the light-blocking layer 451 includes, for example, a region that overlaps with a transistor 102 described later. The light-blocking layer 451 may include a region that overlaps with a transistor 103 described later. The overlap between the light-blocking layer 451 and a transistor can inhibit light from entering the transistor, thereby reducing a leakage current flowing to the transistor, degradation of the transistor, and the like. In particular, the leakage current is preferably reduced when the imaging device employs a global shutter method, in which case leakage of retained electric charge can be inhibited.

Alternatively, it is also possible to employ a structure in which the light-blocking layer 451 does not overlap with transistors included in the circuit portion 901. For example, in the case where a rolling shutter method is employed, a transparent conductive layer 455 described later can be employed instead of the light-blocking layer 451. The use of the transparent conductive layer 455 increases the amount of light entering the photoelectric conversion device 101, thereby increasing the sensitivity of the imaging device in some cases.

The layer 25 may include a shutter. The shutter preferably has a function of controlling light transmittance. The shutter is preferably capable of, for example, switching a light-blocking mode and a light-transmitting mode in accordance with an electric signal. The shutter is preferably provided so as to overlap with at least part of the photoelectric conversion device 101.

A liquid crystal element can be used as the shutter, for example. The liquid crystal element is provided, for example, instead of the light-blocking layer 451. Alternatively, the liquid crystal element is provided so as to overlap with at least one of the light-blocking layer and the color filter. The liquid crystal element is provided, for example, between the layer 24 and the color filter.

A plurality of liquid crystal elements are preferably arranged in a matrix. For example, one liquid crystal element is provided for one pixel. Alternatively, one liquid crystal element may be provided for a plurality of pixels. Alternatively, a plurality of liquid crystal elements may be provided for one pixel.

The transmittance of the liquid crystal element can be controlled by controlling the electric field applied to the liquid crystal element. When the transmittance of the liquid crystal element is reduced by controlling the electric field applied thereto, the liquid crystal element can function as a light-blocking layer.

The liquid crystal element preferably has a structure in which a liquid crystal layer is interposed between a pair of electrodes having light-transmitting properties. With such a structure, the transmittance of the liquid crystal element can be increased by controlling the electric field applied to the liquid crystal element when light does not need to be blocked.

### <Layer 26>

The layer 26 includes a microlens array 462 and an insulating layer 461. The microlens array 462 has a function of condensing incident light and making light efficiently enter the photoelectric conversion device 101.

### <Pixel Circuit 1>

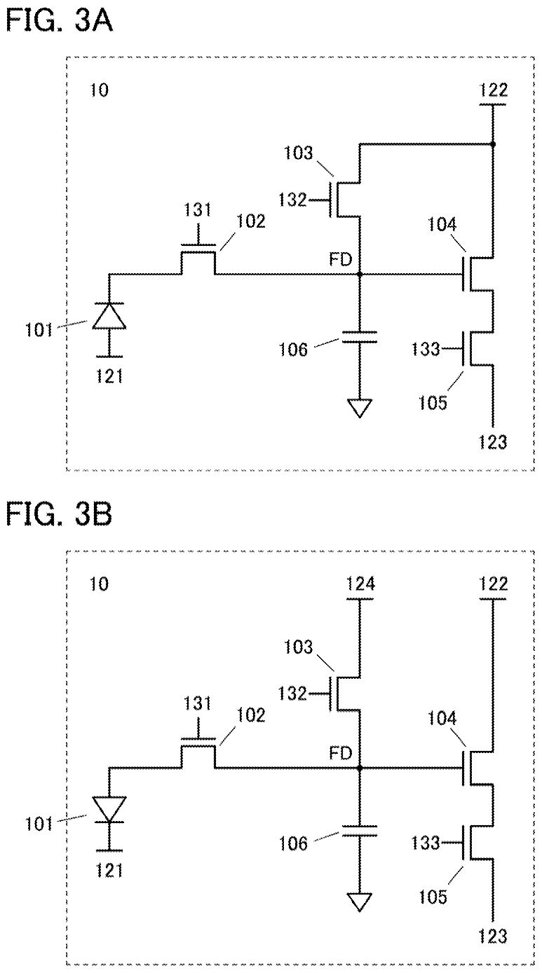

FIG. 3A is a circuit diagram illustrating an example of a pixel 10. The pixel 10 includes the photoelectric conversion device 101, the transistor 102, the transistor 103, a transistor 104, a transistor 105, and a capacitor 106. For example, the transistor 102, the transistor 103, the transistor 104, the transistor 105, and the capacitor 106 can be components included in the circuit portion 901 illustrated in FIG. 2.

One electrode of the photoelectric conversion device 101 is electrically connected to one of a source and a drain of the transistor 102. The other of the source and the drain of the transistor 102 is electrically connected to one of a source and a drain of the transistor 103, a gate of the transistor 104, and one electrode of the capacitor 106. One of a source and a drain of the transistor 104 is electrically connected to the other of the source and the drain of the transistor 105.

Here, a point where the other of the source and the drain of the transistor 102, the one of the source and the drain of the transistor 103, the gate of the transistor 104, and the one electrode of the capacitor 106 are electrically connected is a node FD. The node FD can function as an electric charge detection portion.

The other electrode of the photoelectric conversion device 101 is electrically connected to a wiring 121. The other of the source and the drain of the transistor 103 is electrically connected to a wiring 122. The other of the source and the drain of the transistor 104 is electrically connected to the wiring 122. The other of the source and the drain of the transistor 105 is electrically connected to a wiring 123.

A gate of the transistor 102 is electrically connected to a wiring 131. A gate of the transistor 103 is electrically connected to a wiring 132. A gate of the transistor 105 is electrically connected to a wiring 133.

The wirings 121 and 122 can each function as a power supply line. In the structure illustrated in FIG. 3A, the wiring 121 functions as a low potential power supply line, and the wiring 122 functions as a high potential power supply line.

The wirings 131, 132, and 133 can function as signal lines for controlling conduction of the respective transistors. The wiring 123 can function as an output line, and is electrically connected to a reading circuit including a correlated double sampling circuit (CDS circuit), an A/D converter circuit, and the like, for example.

The transistor 102 has a function of reading out electric charge from the photoelectric conversion device 101 and controlling the potential of the node FD. The transistor 103 has a function of resetting the potential of the node FD. The transistor 104 functions as a component of a source follower circuit. The transistor 105 has a function of selecting output of the pixel.

In the circuit of the pixel 10, the connection relation of the cathode and the anode of the photoelectric conversion device 101 in FIG. 3A may be reversed as illustrated in FIG. 3B. In this case, the other of the source and the drain of the transistor 103 is electrically connected to a wiring 124, the wirings 121 and 122 function as high potential power supply lines, and the wiring 124 functions as a low potential power supply line.

### <Layout 1>

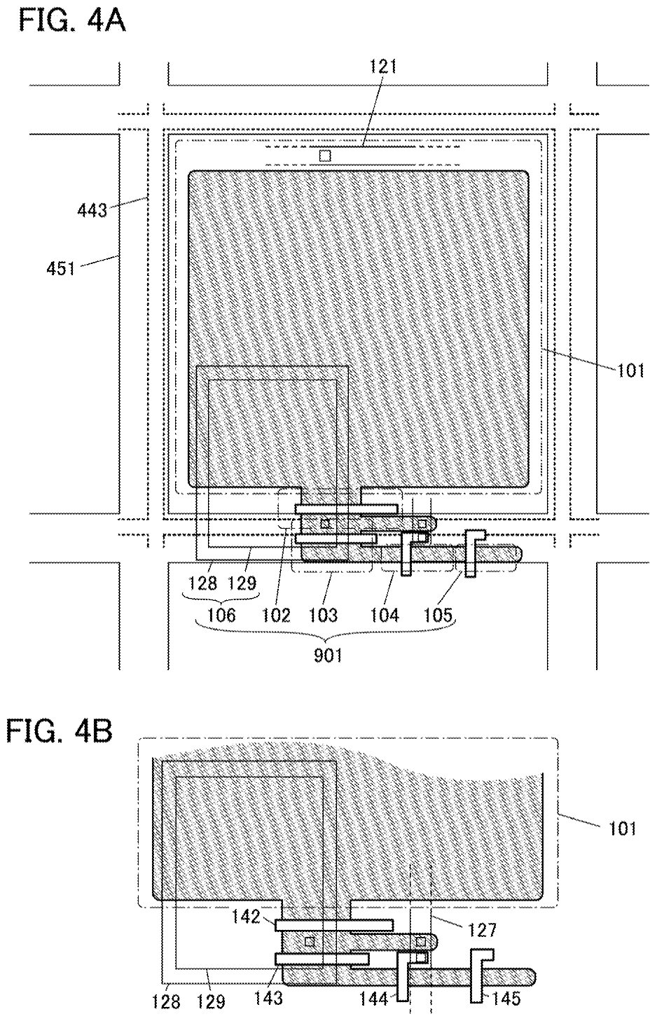

FIG. 4A illustrates a top view example of a simple layout of the components of the pixel illustrated in FIG. 3A and FIG. 3B. FIG. 4B is an enlarged view of the circuit portion 901 and the vicinity thereof in FIG. 4A.

The transistor 102 includes a gate electrode 142 interposed between a source region and a drain region. The transistor 103 includes a gate electrode 143 interposed between a source region and a drain region. The transistor 104 includes a gate electrode 144 interposed between a source region and a drain region. The transistor 105 includes a gate electrode 145 interposed between a source region and a drain region.

In FIG. 4A and FIG. 4B, the one electrode of the photoelectric conversion device 101 and the one of the source and the drain of the transistor 102 are used in common. The other of the source and the drain of the transistor 102 and the one of the source and the drain of the transistor 103 are used in common. The other of the source and the drain of the transistor 102 and the gate electrode 144 of the transistor 104 are electrically connected to each other through a wiring 127. The other electrode of the photoelectric conversion device 101 is electrically connected to the wiring 121. The capacitor 106 includes a wiring 128 functioning as a first electrode and a wiring 129 functioning as a second electrode.

Note that FIG. 4A illustrates an example in which the photoelectric conversion device 101 included in the pixel 10 and the circuit portion 901 are positioned in a region surrounded by an element isolation layer 443.

Here, a variety of transistors can be used as the transistor 102, the transistor 103, the transistor 104, and the transistor 105. For example, a transistor including silicon in a channel formation region (Si transistor) can be used. Alternatively, a transistor including a metal oxide in a channel formation region (OS transistor) can be used, for example. It is also possible to use a transistor including silicon carbide, germanium, silicon germanium, gallium arsenide, gallium aluminum arsenide, indium phosphide, zinc selenide, gallium nitride, gallium oxide, or the like in a channel formation region, for example. These transistors may be used in appropriate combination.

The OS transistor has a feature of an extremely low off-state current. When the transistors with a low off-state current are used as the transistors 102 and 103, the electric charge retention period at the node FD can be elongated greatly, and image data with little deterioration can be read out. That is, a global shutter operation in which all the pixels concurrently perform an image capturing operation is possible. Note that a rolling shutter operation is also possible.

The Si transistor has excellent amplifying characteristics in some cases. Thus, the Si transistor can be favorably used as, for example, the transistor 104.

Having high mobility, the Si transistor can operate at high speed. Thus, the Si transistor can be favorably used as, for example, the transistor 105.

### <Pixel Circuit 2>

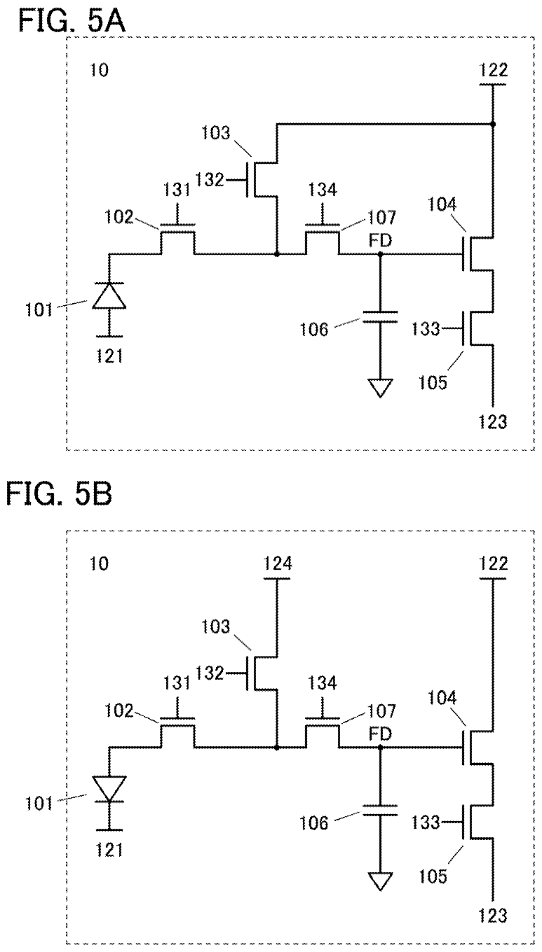

The pixel 10 of one embodiment of the present invention may have any of circuit structures illustrated in FIG. 5A and FIG. 5B. The pixels 10 illustrated in FIG. 5A and FIG. 5B have structures in which a transistor 107 is added to the circuits illustrated in FIG. 3A and FIG. 3B, respectively. One of a source and a drain of the transistor 107 is electrically connected to the one of the source and the drain of the transistor 102 and the one of the source and the drain of the transistor 103. The other of the source and the drain of the transistor 107 is electrically connected to the gate of the transistor 104 and the one electrode of the capacitor 106.

A variety of transistors can be used as the transistor 102, the transistor 103, the transistor 104, and the transistor 105. For example, a transistor including silicon in a channel formation region (Si transistor) can be used. Alternatively, a transistor including a metal oxide in a channel formation region (OS transistor) can be used, for example. It is also possible to use a transistor including silicon carbide, germanium, silicon germanium, gallium arsenide, gallium aluminum arsenide, indium phosphide, zinc selenide, gallium nitride, gallium oxide, or the like in a channel formation region, for example. These transistors may be used in appropriate combination.

Since the OS transistor has a low off-state current, when the OS transistor is used as the transistor 107, electric charge can be retained at the node FD for a long period even in the case where the transistor 102 and the transistor 103 have a relatively high off-state current.

Note that this effect can also be obtained when OS transistors are used as the transistor 102 and the transistor 103. On the other hand, in the case where a Si transistor including a channel formation region in a silicon substrate is used as the transistor 102 and a photodiode including a semiconductor region in a silicon substrate is used as the photoelectric conversion device 101, the transistor 102 and the photoelectric conversion device 101 can be directly connected to each other without through a wiring, achieving a structure with little noise. In such a case, for example, the use of the structure illustrated in FIG. 4A and FIG. 4B and the use of the OS transistor as the transistor 107 achieve the pixel circuit that has little noise and is capable of retaining electric charge at the node FD for a long period.

### <Pixel Operation>

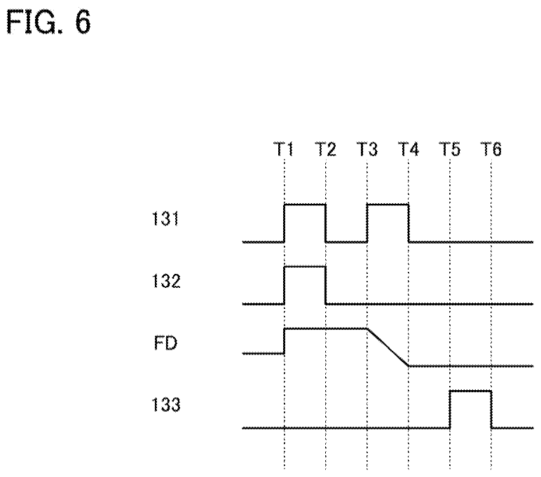

FIG. 6 is a timing chart showing an example of a pixel operation. The pixel circuit illustrated in FIG. 3A can be operated in accordance with the timing chart. The pixel circuit illustrated in FIG. 5A can also be operated by supplying the same signal potential to the wiring 131 and a wiring 134. The pixel circuit illustrated in FIG. 5A may be operated by supplying different signal potentials to the wiring 131 and the wiring 134.

In the description below, “H” represents a potential for turning on a transistor, and “L” represents a potential for turning off a transistor. In addition, the wiring 122 is continuously supplied with a high potential (e.g., VDD), and the wiring 121 is continuously supplied with a low potential (e.g., VSS).

At time T1, when the potential of the wiring 131 is set to “H” and the potential of the wiring 132 is set to “H”, the transistor 102 and the transistor 103 are turned on and the potentials of the node FD and the cathode of the photoelectric conversion device 101 are reset to high potentials.

At time T2, when the potential of the wiring 131 is set to “L” and the potential of the wiring 132 is set to “L”, the transistor 102 is turned off and the photoelectric conversion device 101 starts to accumulate electric charge in accordance with the intensity of emitted light. In addition, the transistor 103 is turned off and the potential of the node FD is retained.

At time T3, when the potential of the wiring 131 is set to “H”, the transistor 102 is turned on, and the electric charge accumulated in the cathode of the photoelectric conversion device 101 is transferred to the node FD. At this time, the potential of the node FD decreases in accordance with the amount of transferred electric charge.

At time T4, when the potential of the wiring 131 is set to “L”, the transistor 102 is turned off, and the potential of the node FD is determined and retained.

At time T5, when the potential of the wiring 133 is set to “H”, the transistor 105 is turned on, the transistor 104 operates in accordance with the potential of the node FD, and data is output to the wiring 123. At Time T6, the potential of the wiring 133 is set to “L” to turn off the transistor 105. The above is the description of the image capturing operation of the pixel.

### <Structure of Imaging Device>

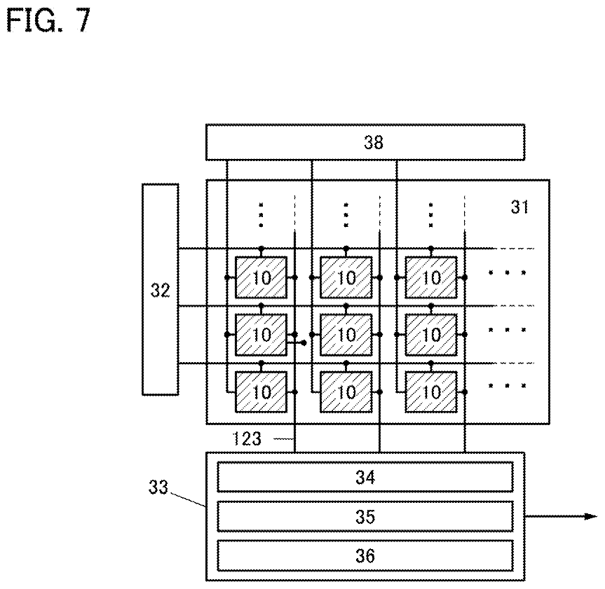

FIG. 7 is a block diagram illustrating the imaging device of one embodiment of the present invention. The imaging device includes a pixel array 31 including the pixels 10 arranged in a matrix, a circuit 32 having a function of selecting a row of the pixel array 31 (row driver), a circuit 33 having a function of reading out data from the pixels 10, and a circuit 38 for supplying a power supply potential. Note that the number of wirings connecting each component is reduced in FIG. 7. The number of each of the circuits 32, 33, and 38 may be more than one.

The circuit 33 can include a circuit 34 for performing correlated double sampling processing on output data of the pixel 10 (CDS circuit), a circuit 35 having a function of converting analog data output from the circuit 34 into digital data (A/D converter circuit or the like), a circuit 36 having a function of selecting a column to which data is output (column driver), and the like.

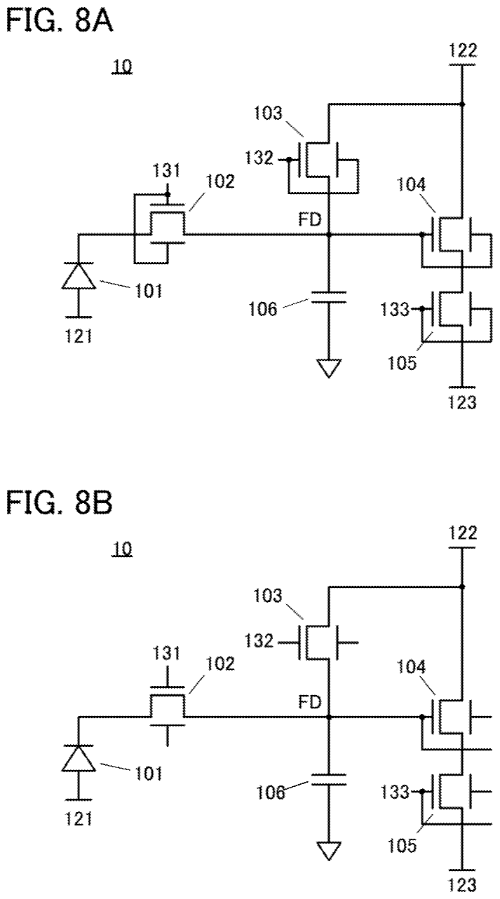

In one embodiment of the present invention, as illustrated in FIG. 8A and FIG. 8B as examples, a structure in which transistors are provided with back gates may be employed. FIG. 8A illustrates a structure in which back gates are electrically connected to front gates, which has an effect of increasing on-state current. Alternatively, as illustrated in FIG. 8B, a structure may be employed in which back gates are supplied with a constant potential. This structure enables control of the threshold voltages of the transistors. Furthermore, the structures of FIG. 8A and FIG. 8B may be included in one circuit. Furthermore, a transistor without a back gate may be provided.

This embodiment can be combined with the description of the other embodiments as appropriate.

### Embodiment 2

In this embodiment, an imaging device having an arithmetic function, which is one embodiment of the present invention, is described with reference to drawings. The imaging device having a stacked-layer structure described in Embodiment 1 can be used as the imaging device described in this embodiment. Note that portions different from those in Embodiment 1 are described on a case-by-case basis. The same components as those in Embodiment 1 are described using common reference numerals.

One embodiment of the present invention is an imaging device having an additional function such as image recognition. The imaging device has a function of retaining analog data (image data) obtained by an image capturing operation in pixels and extracting data obtained by multiplying the analog data by a given weight coefficient. The imaging device has a function of adding the data output from the plurality of pixels (a product-sum operation function).

In addition, when the data taken out from the pixels is taken in a neural network or the like provided inside or outside the imaging device, processing such as image recognition can be performed. Since, in one embodiment of the present invention, an enormous amount of image data can be retained in pixels in an analog data state and an arithmetic operation can be performed in the pixels, processing can be performed efficiently.

### <Imaging Device>

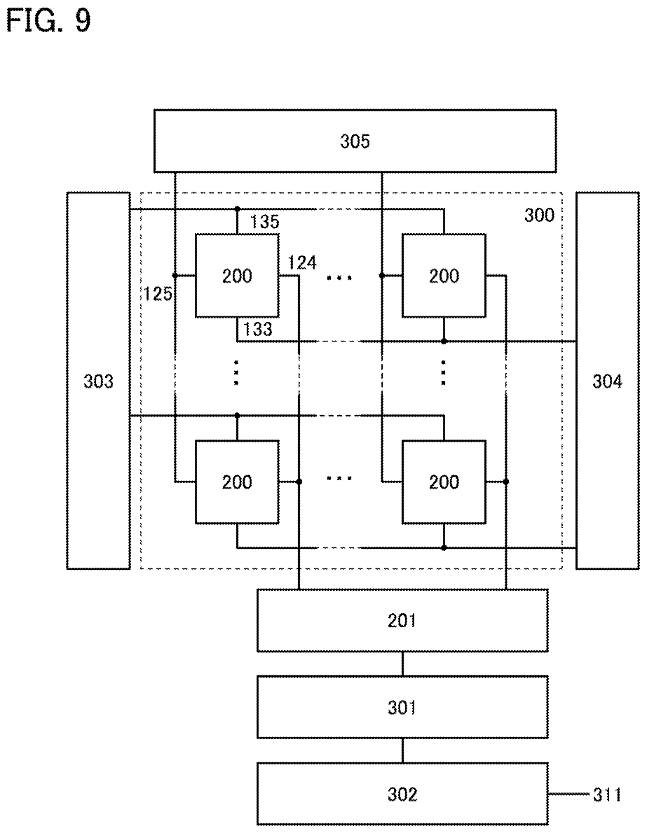

FIG. 9 is a block diagram illustrating the imaging device of one embodiment of the present invention. The imaging device includes a pixel array 300, a circuit 201, a circuit 301, a circuit 302, a circuit 303, a circuit 304, and a circuit 305. Note that one or more of the circuit 201, the circuit 301, the circuit 302, the circuit 303, the circuit 304, and the circuit 305 may include a region overlapping with the pixel array 300. Such a structure can reduce the area of the imaging device.

The imaging device of one embodiment of the present invention may use, instead of the circuit 201 and the circuit 301 to the circuit 305, a circuit having two or more functions of these circuits. Moreover, a circuit other than the circuit 201 and the circuit 301 to the circuit 305 may also be used. Furthermore, one or more of the functions of the circuit 201 and the circuit 301 to the circuit 305 may be replaced by a software operation. Some of the circuit 201 and the circuit 301 to the circuit 305 may be placed outside the imaging device.

The pixel array 300 can have an image capturing function and an arithmetic function. The circuits 201 and 301 can have an arithmetic function. The circuit 302 can have an arithmetic function or a data conversion function and can output data to a wiring 311. The circuits 303 and 304 can have a selection function. The circuit 305 can have a function of supplying a potential (e.g., a weight) to a pixel. As the circuit having a selection function, a shift register, a decoder, or the like can be used.

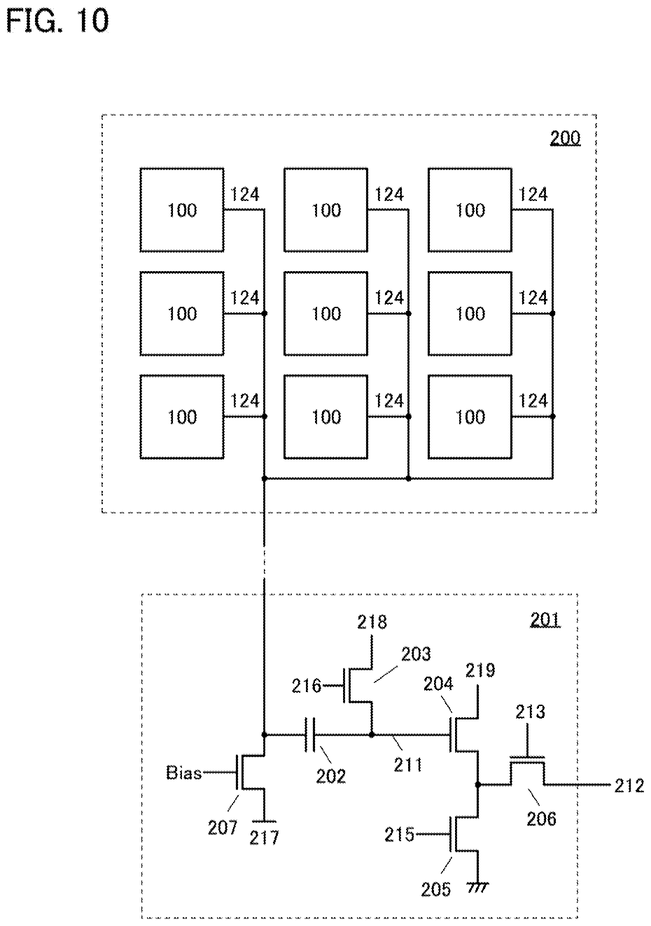

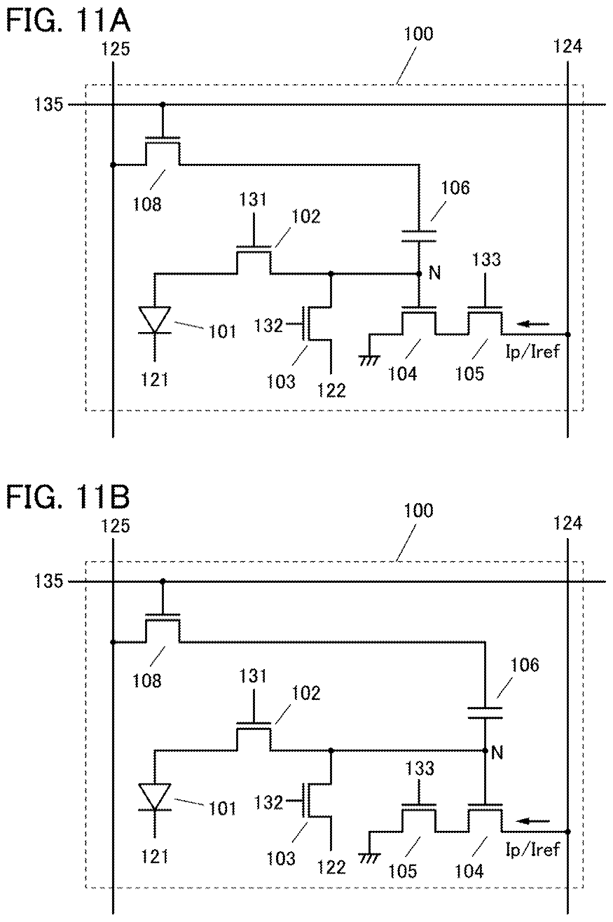

The pixel array 300 includes a plurality of pixel blocks 200. As illustrated in FIG. 10, the pixel block 200 includes a plurality of pixels 100 arranged in a matrix. The pixel 100 includes wirings such as the wiring 124, a wiring 125, the wiring 133, and a wiring 135. The pixel 100 will be described in detail in FIG. 11A and FIG. 11B. Each of the pixels 100 is electrically connected to the circuit 201 through the wiring 124. Note that the circuit 201 can also be provided in the pixel block 200.

The pixels 100 can obtain image data and generate data obtained by adding the image data and a weight coefficient. Note that the number of pixels included in the pixel block 200 is 3×3 in FIG. 10 but is not limited to this example. For example, the number of pixels can be 2×2, 4×4, or the like. Alternatively, the number of pixels in the horizontal direction and the number of pixels in the vertical direction may differ from each other. Furthermore, some pixels may be shared by adjacent pixel blocks.

The pixel block 200 and the circuit 201 can operate as a product-sum operation circuit.

### <Pixel Circuit>

As illustrated in FIG. 11A, the pixel 100 can include the photoelectric conversion device 101, the transistor 102, the transistor 103, the transistor 104, the transistor 105, the capacitor 106, and a transistor 108.

The pixel circuit illustrated in FIG. 11A is different from the pixel circuit illustrated in FIG. 3A, FIG. 3B, and the like in Embodiment 1 in a wiring electrically connected to the transistor 104 and a wiring electrically connected to the transistor 105, and also in that the transistor 108 is included and the other electrode of the capacitor 106 is electrically connected to one of a source and a drain of the transistor 108.

One electrode of the photoelectric conversion device 101 is electrically connected to one of the source and the drain of the transistor 102. The other of the source and the drain of the transistor 102 is electrically connected to one of the source and the drain of the transistor 103, one electrode of the capacitor 106, and the gate of the transistor 104. One of the source and the drain of the transistor 104 is electrically connected to one of the source and the drain of the transistor 105. The other electrode of the capacitor 106 is electrically connected to one of the source and the drain of the transistor 108.

The other electrode of the photoelectric conversion device 101 is electrically connected to the wiring 121. The gate of the transistor 102 is electrically connected to the wiring 131. The other of the source and the drain of the transistor 103 is electrically connected to the wiring 122. The gate of the transistor 103 is electrically connected to the wiring 132. The other of the source and the drain of the transistor 104 is electrically connected to a GND wiring or the like. The other of the source and the drain of the transistor 105 is electrically connected to the wiring 124. The gate of the transistor 105 is electrically connected to the wiring 133. The other of the source and the drain of the transistor 108 is electrically connected to the wiring 125. A gate of the transistor 108 is electrically connected to the wiring 135.

Here, a point where the other of the source and the drain of the transistor 102, the one of the source and the drain of the transistor 103, the one electrode of the capacitor 106, and the gate of the transistor 104 are electrically connected is a node N.

The wirings 121 and 122 can each function as a power supply line. For example, the wiring 121 can function as a high potential power supply line, and the wiring 122 can function as a low potential power supply line. The wirings 131, 132, 133, and 135 can function as signal lines for controlling conduction of the respective transistors. The wiring 125 can function as a wiring for supplying a potential corresponding to a weight coefficient to the pixel 100. The wiring 124 can function as a wiring which electrically connects the pixel 100 and the circuit 201.

Note that an amplifier circuit or a gain control circuit may be electrically connected to the wiring 124.

As the photoelectric conversion device 101, a photodiode can be used. In order to increase the light detection sensitivity under low illuminance conditions, an avalanche photodiode is preferably used.

The transistor 102 can have a function of controlling the potential of the node N. The transistor 103 can have a function of initializing the potential of the node N. The transistor 104 can have a function of controlling a current fed by the circuit 201 in accordance with the potential of the node N. The transistor 105 can have a function of selecting a pixel. The transistor 108 can have a function of supplying the potential corresponding to the weight coefficient to the node N.

Note that as illustrated in FIG. 11B, the transistor 104 and the transistor 105 may be arranged such that the one of the source and the drain of the transistor 104 is electrically connected to the one of the source and the drain of the transistor 105, the other of the source and the drain of the transistor 104 is connected to the wiring 124, and the other of the source and the drain of the transistor 105 is electrically connected to the GND wiring or the like.

In FIG. 11A and FIG. 11B, the connection direction of the pair of electrodes included in the photoelectric conversion device 101 may be reversed. In that case, the wiring 121 functions as a low potential power supply line and the wiring 122 functions as a high potential power supply line.

Here, a variety of transistors can be used as the transistor 102, the transistor 103, the transistor 104, the transistor 105, and the transistor 108. For example, a transistor including silicon in a channel formation region (Si transistor) can be used. Alternatively, a transistor including a metal oxide in a channel formation region (OS transistor) can be used, for example. It is also possible to use a transistor including silicon carbide, germanium, silicon germanium, gallium arsenide, gallium aluminum arsenide, indium phosphide, zinc selenide, gallium nitride, gallium oxide, or the like in a channel formation region, for example. These transistors may be used in appropriate combination.

The OS transistor has a feature of an extremely low off-state current. When OS transistors are used as the transistors 102 and 103, the electric charge retention period at the node N can be elongated greatly. Furthermore, a global shutter mode in which an electric charge accumulation operation is performed in all the pixels at the same time can be employed without complicating the circuit structure and the operation method. Furthermore, while image data is retained at the node N, an arithmetic operation using the image data can be performed a plurality of times.

The Si transistor has excellent amplifying characteristics in some cases. Thus, the Si transistor can be favorably used as, for example, the transistor 104.

Having high mobility, the Si transistor can operate at high speed. Thus, the Si transistor can be favorably used as, for example, the transistor 105 and the transistor 108.

The potential of the node N in the pixel 100 is determined by the potential obtained by adding a reset potential supplied from the wiring 122 and a potential (image data) generated by photoelectric conversion by the photoelectric conversion device 101. Alternatively, the potential of the node N is determined by capacitive coupling of the potential corresponding to a weight coefficient supplied from the wiring 125. Consequently, a current corresponding to data in which a given weight coefficient is added to the image data can be made to flow through the transistor 104.

### <Circuit 201>

As illustrated in FIG. 10, the pixels 100 are electrically connected to each other by the wiring 124. The circuit 201 can perform an arithmetic operation using the sum of currents flowing through the transistors 104 of the pixels 100.

The circuit 201 includes a capacitor 202, a transistor 203, a transistor 204, a transistor 205, a transistor 206, and a transistor 207 as a voltage converter circuit. An appropriate analog potential (Bias) is applied to a gate of the transistor 207.

One electrode of the capacitor 202 is electrically connected to one of a source and a drain of the transistor 203 and a gate of the transistor 204. One of a source and a drain of the transistor 204 is electrically connected to one of a source and a drain of the transistor 205 and one of a source and a drain of the transistor 206. The other electrode of the capacitor 202 is electrically connected to the wiring 124 and one of a source and a drain of the transistor 207.

The other of the source and the drain of the transistor 203 is electrically connected to a wiring 218. The other of the source and the drain of the transistor 204 is electrically connected to a wiring 219. The other of the source and the drain of the transistor 205 is electrically connected to a reference power supply line such as a GND wiring. The other of the source and the drain of the transistor 206 is electrically connected to a wiring 212. The other of the source and the drain of the transistor 207 is electrically connected to a wiring 217. A gate of the transistor 203 is electrically connected to a wiring 216. A gate of the transistor 205 is electrically connected to a wiring 215. A gate of the transistor 206 is electrically connected to a wiring 213.

The wirings 217, 218, and 219 can each have a function of a power supply line. For example, the wiring 218 can have a function of a wiring that supplies a reset potential (Vr) for reading. The wirings 217 and 219 can function as high potential power supply lines. The wirings 213, 215, and 216 can function as signal lines that control the electrical conduction of the respective transistors. The wiring 212 is an output line and can be electrically connected to the circuit 301 illustrated in FIG. 9, for example.

The transistor 203 can have a function of resetting the potential of the wiring 211 to the potential of the wiring 218. The transistors 204 and 205 can have a function of a source follower circuit. The transistor 206 can have a function of controlling reading. The circuit 201 has a function of a correlated double sampling circuit (CDS circuit) and can be replaced with a circuit with another structure that has the function.

In one embodiment of the present invention, offset components other than the product of image data (X) and a weight coefficient (W) are eliminated to extract an objective WX. WX can be calculated using data obtained from the same pixel when light exposure is performed (image capturing is performed) and when light exposure is not performed (image capturing is not performed), and data obtained by adding the weight to these data.

The total amount of currents (Iₚ) flowing through the pixels 100 when light exposure is performed is kΣ(X−Vₜₕ)², and the total amount of currents (Iₚ) flowing through the pixels 100 when the weight is added is kΣ(W+X−Vₜₕ)². The total amount of currents (I_{ref}) flowing through the pixels 100 when light exposure is not performed is kΣ(0−Vₜₕ)², and the total amount of currents (I_{ref}) flowing through the pixels 100 when the weight is added is kΣ(W−Vₜₕ)². Here, k is a constant and Vth is the threshold voltage of the transistor 104.

First, a difference (data A) between the data obtained when light exposure is performed and the data obtained by adding the weight to the data is calculated. The difference is kΣ((X−Vₜₕ)²−(W+X−Vₜₕ)²)=kΣ(−W²−2W·X+2W·Vₜₕ).

Next, a difference (data B) between the data obtained when light exposure is not performed and the data obtained by adding the weight to the data is calculated. The difference is kΣ((0−Vₜₕ)²−(W−Vₜₕ)²)=kΣ(−W²⁺2W·Vₜₕ).

Then, a difference between the data A and the data B is calculated. The difference is kΣ(−W²−2W·X+2W·Vth−(−W²+2W·Vₜₕ))=kΣ(−2W·X). That is, offset components other than the product of the image data (X) and the weight coefficient (W) can be eliminated.

The circuit 201 can read out the data A and the data B. Note that the calculation of the difference between the data A and the data B can be performed by the circuit 301, for example.

### <Image Capturing Operation>

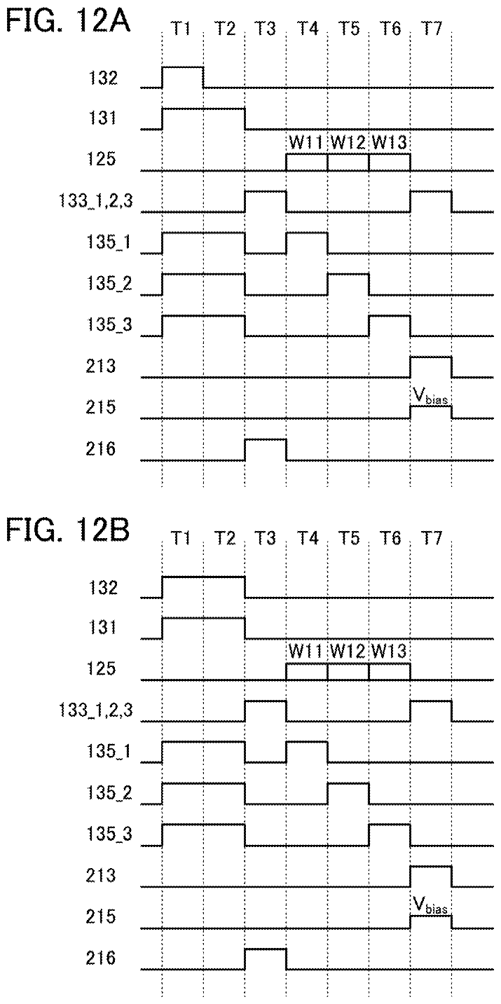

FIG. 12A is a timing chart showing an operation of calculating the difference (data A) between the data obtained when light exposure is performed and the data obtained by adding the weight to the data in the pixel blocks 200 and the circuit 201. For convenience, the timings of changing signals are matched in the chart; however, in reality, the timings are preferably shifted in consideration of the delay inside the circuit. In the following description, a high potential is represented by “H”, and a low potential is represented by “L”.

First, in Period T1, the potential of the wiring 132 is set to “H” and the potential of the wiring 131 is set to “H”, so that the node N in the pixel 100 has a reset potential. Furthermore, the potential of the wiring 125 is brought to “L” and the potentials of wirings 135_1 to 135_3 (the wirings 135 in the first row to the third row) are brought to “H”, so that a weight coefficient 0 is written.

In Period T2, the potential of the wiring 131 is kept at “H” and the potential of the wiring 132 is set to “L”, so that the potential X (image data) is written to the node N by photoelectric conversion of the photoelectric conversion device 101.

In Period T3, the potentials of the wirings 133 (a wiring 133_1, a wiring 133_2, and a wiring 133_3) connected to the pixels 100 in the first row, the pixels 100 in the second row, and the pixels 100 in the third row, respectively, are set to “H”, so that all of the pixels 100 in the pixel blocks are selected. At this time, a current corresponding to the potential X flows to the transistor 104 in each of the pixels 100. The potential of the wiring 216 is set to “H”, so that the potential Vr of the wiring 218 is written to the wiring 211. The operation in Periods T1 to T3 corresponds to obtainment of the data obtained when light exposure is performed, and the data is initialized to the potential Vr of the wiring 211.

In Period T4, the potential of the wiring 125 is set to a potential corresponding to a weight coefficient W11 (a weight added to the pixels in the first row), and the potential of the wiring 135_1 is set to “H”, so that the weight coefficient W11 is added to the nodes N of the pixels 100 in the first row by capacitive coupling of the capacitors 106.

In Period T5, the potential of the wiring 125 is set to a potential corresponding to a weight coefficient W12 (a weight added to the pixels in the second row), and the potential of the wiring 135_2 is set to “H”, so that the weight coefficient W12 is added to the nodes N of the pixels 100 in the second row by capacitive coupling of the capacitors 106.

In Period T6, the potential of the wiring 125 is set to a potential corresponding to a weight coefficient W13 (a weight added to the pixels in the third row), and the potential of the wiring 135_3 is set to “H”, so that the weight coefficient W13 is added to the nodes N of the pixels 100 in the third row by capacitive coupling of the capacitors 106. The operation in Period T4 to Period T6 corresponds to generation of data in which weights are added to the data obtained when image capturing is performed.

In Period T7, the potentials of the wirings 133_1, the wiring 133_2, and the wiring 133_3 are set to “H”, so that all of the pixels 100 in the pixel blocks are selected. At this time, a current corresponding to the potential W11+X flows to the transistors 104 in the pixels 100 in the first row. A current corresponding to the potential W12+X flows to the transistors 104 in the pixels 100 in the second row. A current corresponding to the potential W13+X flows to the transistors 104 in the pixels 100 in the third row.

Here, the potential of the other electrode of the capacitor 202 changes in accordance with the current flowing through the wiring 124, and an amount Y of change is added to the potential Vr of the wiring 211 by capacitive coupling. Accordingly, the potential of the wiring 211 becomes “Vr+Y”. Here, given that Vr=0, Y is the difference itself, which means that the data A is calculated.

The potential of the wiring 213 is set to “H” and the potential of the wiring 215 is set to an appropriate analog potential such as “Was”, so that the circuit 201 can output a signal potential in accordance with the data A of the pixel blocks 200 in the first row by a source follower operation.

FIG. 12B is a timing chart showing an operation of calculating the difference (data B) between the data obtained when light exposure is not performed and the data obtained by adding the weight to the data in the pixel blocks 200 and the circuit 201. Note that the data B may be obtained as needed. For example, the obtained data B may be stored in a memory, and if the input weight is not changed, the data B may be read out from the memory. Note that a plurality of pieces of data B corresponding to a plurality of weights may be stored in the memory. Either the data A or the data B may be obtained first.

First, in Periods T1 and T2, the potential of the wiring 132 is set to “H” and the potential of the wiring 131 is set to “H”, so that the node N in the pixel 100 has a reset potential (0). At the end of Period T2, the potential of the wiring 132 is set to “L” and the potential of the wiring 131 is set to “L”. That is, in these periods, the potential of the node N is the reset potential regardless of the operation of the photoelectric conversion device 101.

In addition, in Period T1, the potential of the wiring 125 is set to “L” and the wirings 135_1, 135_2, and 135_3 are set to “H”, so that a weight coefficient 0 is written. This operation is performed during a period in which the potential of the node N is the reset potential.

In Period T3, the potentials of the wiring 133_1, the wiring 133_2, and the wiring 133_3 are set to “H”, so that all of the pixels 100 in the pixel blocks are selected. At this time, a current corresponding to the reset potential flows to the transistor 104 in each of the pixels 100. The potential of the wiring 216 is set to “H”, so that the potential Vr of the wiring 218 is written to the wiring 211. The operation in Periods T1 to T3 corresponds to obtainment of the data obtained when light exposure is not performed, and the data is initialized to the potential Vr of the wiring 211.

In Period T4, the potential of the wiring 125 is set to a potential corresponding to the weight coefficient W11 (the weight added to the pixels in the first row), and the potential of the wiring 135_1 is set to “H”, so that the weight coefficient W11 is added to the nodes N of the pixels 100 in the first row by capacitive coupling of the capacitors 106.

In Period T5, the potential of the wiring 125 is set to a potential corresponding to the weight coefficient W12 (the weight added to the pixels in the second row), and the potential of the wiring 135_2 is set to “H”, so that the weight coefficient W12 is added to the nodes N of the pixels 100 in the second row by capacitive coupling of the capacitors 106.

In Period T6, the potential of the wiring 125 is set to a potential corresponding to the weight coefficient W13 (the weight added to the pixels in the third row), and the potential of the wiring 135_3 is set to “H”, so that the weight coefficient W13 is added to the nodes N of the pixels 100 in the third row by capacitive coupling of the capacitors 106. The operation in Period T4 to Period T6 corresponds to generation of data in which weights are added to the data obtained when image capturing is not performed.

In Period T7, the potentials of the wiring 133_1, the wiring 133_2, and the wiring 133_3 are set to “H”, so that all of the pixels 100 in the pixel blocks are selected. At this time, a current corresponding to the potential W11+0 flows to the transistors 104 in the pixels 100 in the first row. A current corresponding to the potential W12+0 flows to the transistors 104 in the pixels 100 in the second row. A current corresponding to the potential W13+0 flows to the transistors 104 in the pixels 100 in the third row.

Here, the potential of the other electrode of the capacitor 202 changes in accordance with the current flowing through the wiring 124, and the amount Y of change is added to the potential Vr of the wiring 211. Accordingly, the potential of the wiring 211 becomes “Vr+Y”. Here, given that Vr=0, Z is the difference itself, which means that the data B is calculated.

The potential of the wiring 213 is set to “H” and the potential of the wiring 215 is set to an appropriate analog potential (V_{bias}) or the like, so that the circuit 201 can output a signal potential in accordance with the data B of the pixel blocks 200 in the first row by a source follower operation.

The data A and the data B output from the circuit 201 through the above operation are input to the circuit 301. Calculation of the difference between the data A and the data B is performed in the circuit 301, so that unnecessary offset components other than the product of the image data (potential X) and the weight coefficient (potential W) can be eliminated. The circuit 301 may have a structure in which the difference is calculated by utilizing a memory circuit and software processing, other than the structure including an arithmetic circuit such as the circuit 201.

Note that in the above operation, the potential of the wiring 211 of the circuit 201 is initialized to the potential “Vr” both in the operation of obtaining the data A and the operation of obtaining the data B. Then, “(Vr+Y)−(Vr+Z)”=“Y−Z” in the following difference calculation, so that the component of the potential “Vr” is eliminated. As described above, the other unnecessary offset components are also eliminated, so that the product of the image data (potential X) and the weight coefficient (potential W) can be extracted.

This operation corresponds to the initial operation of a neural network performing inference or the like. Thus, at least one arithmetic operation can be performed in the imaging device before an enormous amount of image data is taken out to the outside, so that a load reduction, higher-speed processing, and reduction in power consumption in an arithmetic operation in the outside, input and output of data, or the like are achieved.

Alternatively, as an operation other than the operation described above, the potential of the wiring 211 of the circuit 201 may be initialized to different potentials in the operation of obtaining the data A and in the operation of obtaining the data B. For example, the potential of the wiring 211 is initialized to a potential “Vr1” in the operation of obtaining the data A and to a potential “Vr2” in the operation of obtaining the data B. In this case, “(Vr1+Y)−(Vr2+Z)”=“(Vr1−Vr2)+(Y−Z)” in the following difference calculation. “Y−Z” is extracted as the product of the image data (potential X) and the weight coefficient (potential W) as in the above operation, and “Vr1−Vr2” is added. Here, “Vr1−Vr2” corresponds to a bias used for threshold value adjustment in the arithmetic operation in a middle layer of the neural network.

Furthermore, the weight has a function of, for example, a filter of a convolutional neural network (CNN) and may additionally have a function of amplifying or attenuating data. For example, when the weight coefficient (W) in the operation of obtaining the data A is set to the product of data obtained by the filter processing and an amplified amount, the product of the image data and the weight coefficient in the filter processing can be amplified and data corrected to a brighter image can be extracted. The data B is data obtained when image capturing is not performed and thus can also be referred to as black level data. Thus, the operation of calculating the difference between the data A and the data B can be an operation of promoting visualization of an image taken in a dark place. That is, luminance correction using a neural network can be performed.

As described above, a bias can be generated by the operation in the imaging device in one embodiment of the present invention. Furthermore, a functional weight can be added in the imaging device. Thus, a load in an arithmetic operation or the like performed in the outside can be reduced and the imaging device can be employed for a variety of usages. For example, part of processing in inference of a subject, correction of the definition of image data, correction of luminance, generation of a color image from a monochrome image, generation of a three-dimensional image from a two-dimensional image, restoration of defected information, generation of a moving image from a still image, correction of an out-of-focus image, or the like can be performed in the imaging device.

### <Circuits 301 and 302>

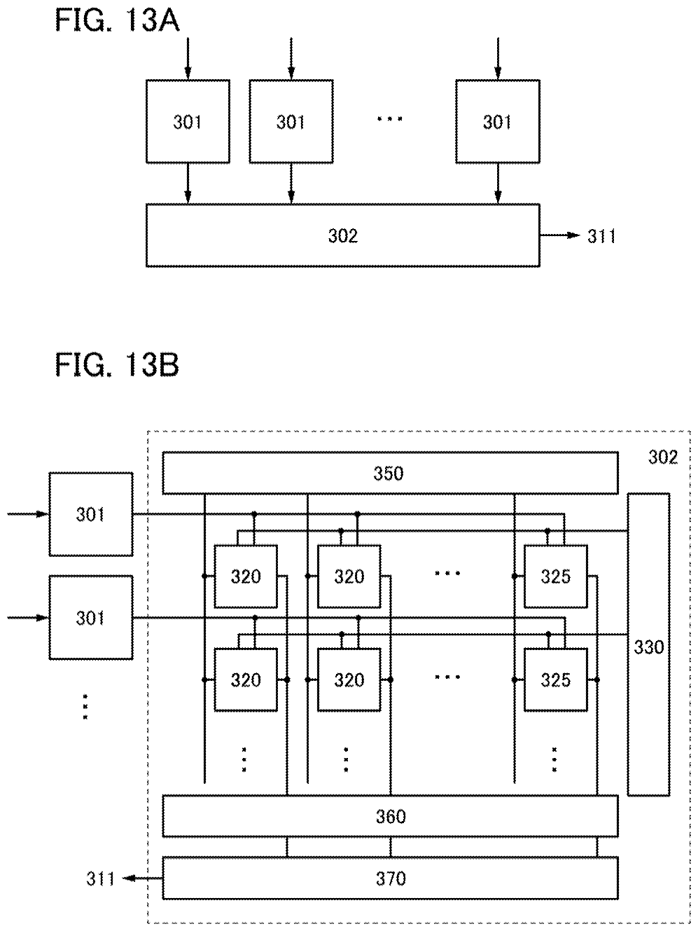

FIG. 13A is a diagram illustrating the circuits 301 connected to the circuit 201, and the circuit 302. Product-sum operation result data output from the circuit 201 is sequentially input to the circuits 301. The circuits 301 may have a variety of arithmetic functions in addition to the above-described function of calculating the difference between the data A and the data B. For example, the circuits 301 can have a structure similar to that of the circuit 201. Alternatively, the function of the circuits 301 may be replaced by software processing.

In addition, the circuit 301 may include a circuit that performs an arithmetic operation of an activation function. A comparator circuit can be used as the circuit, for example. A comparator circuit outputs a result of comparing input data and a set threshold as binary data. In other words, the pixel blocks 200 and the circuits 301 can operate as some components of a neural network.

The circuits 301 may include an A/D converter. When image data is output to the outside from the pixel blocks 200 with or without undergoing an arithmetic operation, the analog data can be converted into digital data by the circuits 301.

For example, in the pixel block 200 including 3×3 pixels 100, when the same weight (e.g., 0) is supplied to all the pixels 100 and the transistor 108 included in the pixel from which data is to be output is turned on, the sum of image data of the whole pixel block 200, the row-basis sum of image data, data from each pixel, or the like can be output from the pixel block 200.

In the case where the data output from the pixel blocks 200, which corresponds to image data of a plurality of bits, can be binarized by the circuits 301, the binarization can be rephrased as compression of image data.

Data output from the circuits 301 is sequentially input to the circuit 302. The circuit 302 can have a structure including a latch circuit, a shift register, and the like, for example. With this structure, parallel—serial conversion can be performed and data input in parallel can be output to the wiring 311 as serial data.

Moreover, as illustrated in FIG. 13B, the circuit 302 may include a neural network. The neural network includes memory cells arranged in a matrix, and each memory cell retains a weight coefficient. Data output from the circuits 301 is input to corresponding memory cells 320, and a product-sum operation can be performed. Note that the number of memory cells illustrated in FIG. 13B is an example, and the number is not limited thereto. Data after the product-sum operation can be output to the wiring 311.

Note that the connection destination of the wiring 311 is not limited in FIG. 13A and FIG. 13B. For example, the wiring 311 can be connected to a neural network, a memory device, a communication device, or the like.

The neural network illustrated in FIG. 13B includes the memory cells 320 and reference memory cells 325 which are arranged in a matrix, a circuit 330, a circuit 350, a circuit 360, and a circuit 370.

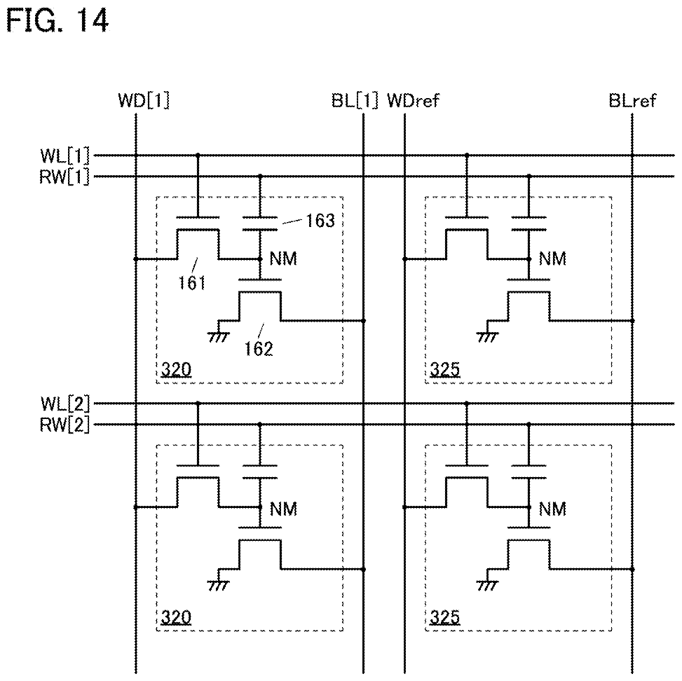

FIG. 14 illustrates an example of the memory cells 320 and the reference memory cells 325. The reference memory cells 325 are provided in any one column. The memory cells 320 and the reference memory cells 325 have similar structures and each include a transistor 161, a transistor 162, and a capacitor 163.

One of a source and a drain of the transistor 161 is electrically connected to a gate of the transistor 162. The gate of the transistor 162 is electrically connected to one electrode of the capacitor 163. Here, a point where the one of the source and the drain of the transistor 161, the gate of the transistor 162, and the one electrode of the capacitor 163 are connected is a node NM.

A gate of the transistor 161 is electrically connected to a wiring WL. The other electrode of the capacitor 163 is electrically connected to a wiring RW. One of a source and a drain of the transistor 162 is electrically connected to a reference potential wiring such as a GND wiring.

In the memory cell 320, the other of the source and the drain of the transistor 161 is electrically connected to a wiring WD. The other of the source and the drain of the transistor 162 is electrically connected to a wiring BL.

In the reference memory cell 325, the other of the source and the drain of the transistor 161 is electrically connected to a wiring WDref. The other of the source and the drain of the transistor 162 is electrically connected to a wiring BLref.

The wiring WL is electrically connected to the circuit 330. As the circuit 330, a decoder, a shift register, or the like can be used.

The wiring RW is electrically connected to the circuit 301. Binary data output from the circuit 301 is written to each memory cell. Note that a sequential circuit such as a shift register may be provided between the circuit 301 and each of the memory cells.

The wiring WD and the wiring WDref are electrically connected to the circuit 350. As the circuit 350, a decoder, a shift register, or the like can be used. Furthermore, the circuit 350 may include a D/A converter or an SRAM. The circuit 350 can output a weight coefficient to be written to the node NM.

The wiring BL and the wiring BLref are electrically connected to the circuit 360. The circuit 360 can have a structure equivalent to that of the circuit 201. By the circuit 360, a signal of a product-sum operation result from which offset components are eliminated can be obtained.

The circuit 360 is electrically connected to the circuit 370. The circuit 370 can also be referred to as an activation function circuit. The activation function circuit has a function of performing an arithmetic operation for converting the signal input from the circuit 360 in accordance with a predefined activation function. As the activation function, for example, a sigmoid function, a tanh function, a softmax function, a ReLU function, a threshold function, or the like can be used. The signal converted by the activation function circuit is output to the outside as output data.

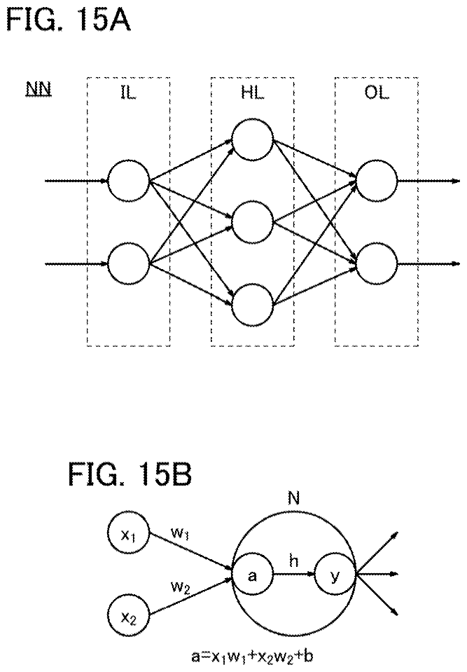

As illustrated in FIG. 15A, a neural network NN can be formed of an input layer IL, an output layer OL, and a middle layer (hidden layer) HL. The input layer IL, the output layer OL, and the middle layer HL each include one or more neurons (units). Note that the middle layer HL may be composed of one layer or two or more layers. A neural network including two or more middle layers HL can also be referred to as a DNN (deep neural network). Learning using a deep neural network can also be referred to as deep learning.

Input data is input to each neuron in the input layer IL. An output signal of a neuron in the previous layer or the subsequent layer is input to each neuron in the middle layer HL. To each neuron in the output layer OL, output signals of the neurons in the previous layer are input. Note that each neuron may be connected to all the neurons in the previous and subsequent layers (full connection), or may be connected to some of the neurons.

FIG. 15B illustrates an example of an arithmetic operation with the neurons. Here, a neuron N and two neurons in the previous layer which output signals to the neuron N are illustrated. An output x₁ of a neuron in the previous layer and an output x₂ of a neuron in the previous layer are input to the neuron N. Then, in the neuron N, a total sum x₁w₁+x₂w₂ of a multiplication result (x₁w₁) of the output x₁ and a weight w₁ and a multiplication result (x₂w₂) of the output x₂ and a weight w₂ is calculated, and then a bias b is added as necessary, so that the value a=x₁w₁+x₂w₂+b is obtained. Then, the value a is converted with an activation function h, and an output signal y=ah is output from the neuron N.

In this manner, the arithmetic operation with the neurons includes the arithmetic operation that sums the products of the outputs and the weights of the neurons in the previous layer, that is, the product-sum operation (x₁w₁+x₂w₂ described above). This product-sum operation may be performed using a program on software or may be performed using hardware.

In one embodiment of the present invention, an analog circuit is used as hardware to perform a product-sum operation. In the case where an analog circuit is used as the product-sum operation circuit, the circuit scale of the product-sum operation circuit can be reduced, or higher processing speed and lower power consumption can be achieved by reduced frequency of access to a memory.

The product-sum operation circuit preferably has a structure including an OS transistor. An OS transistor is suitably used as a transistor included in an analog memory of the product-sum operation circuit because of its extremely low off-state current. Note that the product-sum operation circuit may be formed using both a Si transistor and an OS transistor.

This embodiment can be combined with the description of the other embodiments as appropriate.

### Embodiment 3

In this embodiment, structure examples and the like of the imaging device of one embodiment of the present invention are described.

### <Photoelectric Conversion Device>

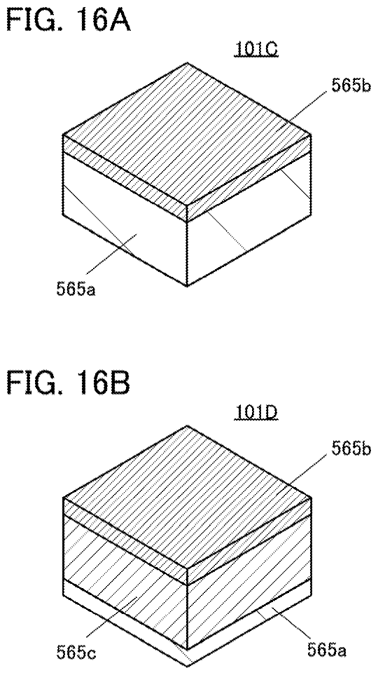

A photoelectric conversion device 101C illustrated in FIG. 16A is an example of the structure that can be used for the photoelectric conversion device 101 included in the layer 24 described in Embodiment 1. The photoelectric conversion device 101C can include a layer 565a and a layer 565b. Note that the layer may be replaced with a region in some cases.

The photoelectric conversion device 101C is a pn-junction photodiode; for example, a p-type semiconductor can be used for the layer 565a, and an n-type semiconductor can be used for the layer 565b. Alternatively, an n-type semiconductor may be used for the layer 565a, and a p-type semiconductor may be used for the layer 565b.

The structure of a photoelectric conversion device 101D illustrated in FIG. 16B may be used for the photoelectric conversion device 101. The photoelectric conversion device 101D is a pin-junction photodiode; for example, a p-type semiconductor can be used for the layer 565a, an i-type semiconductor can be used for a layer 565c, and an n-type semiconductor can be used for the layer 565b. Alternatively, an n-type semiconductor may be used for the layer 565a, and a p-type semiconductor may be used for the layer 565b.

The pn-junction photodiode and the pin-junction diode can be typically formed using single crystal silicon.

### <Os Transistor>

Next, an OS transistor that can be used in the pixel circuit of one embodiment of the present invention is described.

As a semiconductor material used for an OS transistor, a metal oxide whose energy gap is greater than or equal to 2 eV, preferably greater than or equal to 2.5 eV, further preferably greater than or equal to 3 eV can be used. A typical example is an oxide semiconductor containing indium, and a CAAC-OS or a CAC-OS, each of which will be described later, or the like can be used, for example. A CAAC-OS has a crystal structure including stable atoms and is suitable for a transistor that is required to have high reliability, and the like. A CAC-OS has high mobility and is suitable for a transistor that operates at high speed, and the like.

A semiconductor layer of an OS transistor has a large energy gap, and thus the OS transistor has an extremely low off-state current of several yoctoamperes per micrometer (current per micrometer of a channel width). An OS transistor has features such that impact ionization, an avalanche breakdown, a short-channel effect, and the like do not occur, which are different from those of a Si transistor. Hence, the use of an OS transistor enables formation of a circuit having high withstand voltage and high reliability. Moreover, variations in electrical characteristics due to crystallinity unevenness, which are caused in Si transistors, are less likely to occur in OS transistors.

A semiconductor layer included in an OS transistor can be, for example, a film represented by an In—M—Zn-based oxide that contains indium, zinc, and M (M is one or more selected from metals such as aluminum, titanium, gallium, germanium, yttrium, zirconium, lanthanum, cerium, tin, neodymium, and hafnium). The In—M—Zn-based oxide can be formed by, for example, a sputtering method, an ALD (Atomic layer deposition) method, or an MOCVD (Metal organic chemical vapor deposition) method.

In the case where the In—M—Zn-based oxide is deposited by a sputtering method, it is preferable that the atomic ratio of the metal elements in a sputtering target satisfy In M and Zn M. The atomic ratio of the metal elements in such a sputtering target is preferably, for example, In:M:Zn=1:1:1, In:M:Zn=1:1:1.2, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, or In:M:Zn=10:1:3. Note that the atomic ratio in the formed semiconductor layer varies from the above atomic ratio of the metal elements of the sputtering target in a range of ±40%.

An oxide semiconductor with a low carrier density is used for the semiconductor layer. For example, for the semiconductor layer, it is possible to use an oxide semiconductor whose carrier density is lower than or equal to 1×10¹⁷/cm³, preferably lower than or equal to 1×10¹⁵/cm³, further preferably lower than or equal to 1×10¹³/cm³, still further preferably lower than or equal to 1×10¹¹/cm³, even further preferably lower than 1×10¹⁰/cm³, and higher than or equal to 1×10⁻⁹/cm³. Such an oxide semiconductor is referred to as a highly purified intrinsic or substantially highly purified intrinsic oxide semiconductor. The oxide semiconductor has a low density of defect states and can thus be referred to as an oxide semiconductor having stable characteristics.

Note that the composition is not limited to those described above, and an oxide semiconductor having an appropriate composition can be used depending on required semiconductor characteristics and electrical characteristics (e.g., field-effect mobility and threshold voltage) of the transistor. To obtain the required semiconductor characteristics of the transistor, it is preferable that the carrier density, the impurity concentration, the defect density, the atomic ratio between metal elements and oxygen, the interatomic distance, the density, or the like of the semiconductor layer be set to appropriate values.

When silicon or carbon, which is one of elements belonging to Group 14, is contained in the oxide semiconductor included in the semiconductor layer, oxygen vacancies are increased, and the semiconductor layer becomes n-type. Thus, the concentration of silicon or carbon (the concentration obtained by secondary ion mass spectrometry) in the semiconductor layer is set lower than or equal to 2×10¹⁸ atoms/cm³, preferably lower than or equal to 2×10¹⁷ atoms/cm³.

Alkali metal and alkaline earth metal might generate carriers when bonded to an oxide semiconductor, in which case the off-state current of the transistor might be increased. Therefore, the concentration of alkali metal or alkaline earth metal (the concentration obtained by secondary ion mass spectrometry) in the semiconductor layer is set lower than or equal to 1×10¹⁸ atoms/cm³, preferably lower than or equal to 2×10¹⁶ atoms/cm³.

When nitrogen is contained in the oxide semiconductor included in the semiconductor layer, electrons serving as carriers are generated and the carrier density increases, so that the semiconductor layer easily becomes n-type. As a result, a transistor using an oxide semiconductor that contains nitrogen is likely to have normally-on characteristics. Hence, the nitrogen concentration (the concentration obtained by secondary ion mass spectrometry) in the semiconductor layer is preferably set lower than or equal to 5×10¹⁸ atoms/cm³.

When hydrogen is contained in the oxide semiconductor included in the semiconductor layer, hydrogen reacts with oxygen bonded to a metal atom to be water, and thus sometimes forms oxygen vacancies in the oxide semiconductor. If the channel formation region in the oxide semiconductor includes oxygen vacancies, the transistor sometimes has normally-on characteristics. In some cases, a defect in which hydrogen enters oxygen vacancies functions as a donor and generates an electron serving as a carrier. In other cases, bonding of part of hydrogen to oxygen bonded to a metal atom generates electrons serving as carriers. Thus, a transistor using an oxide semiconductor that contains a large amount of hydrogen is likely to have normally-on characteristics.

A defect in which hydrogen enters oxygen vacancies can function as a donor of the oxide semiconductor. However, it is difficult to evaluate the defects quantitatively. Thus, the oxide semiconductor is sometimes evaluated by not its donor concentration but its carrier concentration. Therefore, in this specification and the like, the carrier concentration assuming the state where an electric field is not applied is sometimes used, instead of the donor concentration, as the parameter of the oxide semiconductor. That is, “carrier concentration” in this specification and the like can be replaced with “donor concentration” in some cases.

Therefore, hydrogen in the oxide semiconductor is preferably reduced as much as possible. Specifically, the hydrogen concentration in the oxide semiconductor, which is obtained by secondary ion mass spectrometry (SIMS), is lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³. When an oxide semiconductor with sufficiently reduced impurities such as hydrogen is used for a channel formation region of a transistor, the transistor can have stable electrical characteristics.

The semiconductor layer may have a non-single-crystal structure, for example. Examples of the non-single-crystal structure include a CAAC-OS (C-Axis Aligned Crystalline Oxide Semiconductor) including a c-axis aligned crystal, a polycrystalline structure, a microcrystalline structure, and an amorphous structure. Among the non-single-crystal structures, the amorphous structure has the highest density of defect states, whereas the CAAC-OS has the lowest density of defect states.

An oxide semiconductor film having an amorphous structure has disordered atomic arrangement and no crystalline component, for example. Alternatively, an oxide film having an amorphous structure has, for example, a completely amorphous structure and no crystal part.

Note that the semiconductor layer may be a mixed film including two or more of a region having an amorphous structure, a region having a microcrystalline structure, a region having a polycrystalline structure, a CAAC-OS region, and a region having a single crystal structure. The mixed film has, for example, a single-layer structure or a stacked-layer structure including two or more of the above-described regions in some cases.

The composition of a CAC (Cloud-Aligned Composite)-OS, which is one embodiment of a non-single-crystal semiconductor layer, is described below.

A CAC-OS refers to one composition of a material in which elements constituting an oxide semiconductor are unevenly distributed with a size greater than or equal to 0.5 nm and less than or equal to 10 nm, preferably greater than or equal to 1 nm and less than or equal to 2 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 2 nm, or a similar size in an oxide semiconductor is hereinafter referred to as a mosaic pattern or a patch-like pattern.

Note that an oxide semiconductor preferably contains at least indium. In particular, indium and zinc are preferably contained. In addition, one or more kinds selected from aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like may be contained.

For example, a CAC-OS in an In—Ga—Zn oxide (of the CAC-OS, an In—Ga—Zn oxide may be particularly referred to as CAC-IGZO) has a composition in which materials are separated into indium oxide (hereinafter InO_{X1}, where X1 is a real number greater than 0) or indium zinc oxide (hereinafter In_{X2}Zn_{Y2}O_{Z2}, where X2, Y2, and Z2 are real numbers greater than 0), and gallium oxide (hereinafter GaO_{X3}, where X3 is a real number greater than 0) or gallium zinc oxide (hereinafter Ga_{X4}Zn_{Y4}O_{Z4}, where X4, Y4, and Z4 are real numbers greater than 0), for instance, to form a mosaic pattern, and InO_{X1} or In_{X2}Zn_{Y2}O_{Z2} forming the mosaic pattern is evenly distributed in the film (this composition is also referred to as a cloud-like composition).

That is, the CAC-OS is a composite oxide semiconductor having a composition in which a region including GaO_{X3} as a main component and a region including In_{X2}Zn_{Y2}O_{Z2} or InO_{X1} as a main component are mixed. Note that in this specification, for example, when the atomic ratio of In to the element M in a first region is greater than the atomic ratio of In to the element M in a second region, the first region is regarded as having a higher In concentration than the second region.

Note that IGZO is a common name, which may specify a compound containing In, Ga, Zn, and O. A typical example is a crystalline compound represented by InGaO₃(ZnO)ₘ₁ (m1 is a natural number) or In₍₁₊ₓ₀₎Ga₍₁₋ₓ₀₎O₃(ZnO)ₘ₀ (−1≤x0≤1; m0 is a given number).

The above crystalline compounds have a single crystal structure, a polycrystalline structure, or a CAAC structure. Note that the CAAC structure is a crystal structure in which a plurality of IGZO nanocrystals have c-axis alignment and are connected in the a-b plane without alignment.

On the other hand, the CAC-OS relates to the material composition of an oxide semiconductor. The CAC-OS refers to a composition in which, in the material composition containing In, Ga, Zn, and O, some regions that contain Ga as a main component and are observed as nanoparticles and some regions that contain In as a main component and are observed as nanoparticles are randomly dispersed in a mosaic pattern. Therefore, the crystal structure is a secondary element for the CAC-OS.

Note that in the CAC-OS, a stacked-layer structure including two or more films with different compositions is not included. For example, a two-layer structure of a film containing In as a main component and a film containing Ga as a main component is not included.

A boundary between the region containing GaO_{X3} as a main component and the region containing In_{X2}Zn_{Y2}O_{Z2} or InO_{X1} as a main component is not clearly observed in some cases.

Note that in the case where one kind or a plurality of kinds selected from aluminum, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like are contained instead of gallium, the CAC-OS refers to a composition in which some regions that include the metal element(s) as a main component and are observed as nanoparticles and some regions that include In as a main component and are observed as nanoparticles are randomly dispersed in a mosaic pattern.

The CAC-OS can be formed by a sputtering method under a condition where a substrate is not heated, for example. Moreover, in the case of forming the CAC-OS by a sputtering method, any one or more selected from an inert gas (typically, argon), an oxygen gas, and a nitrogen gas are used as a deposition gas. The ratio of the flow rate of the oxygen gas to the total flow rate of the deposition gas in deposition is preferably as low as possible, and for example, the ratio of the flow rate of the oxygen gas is higher than or equal to 0% and lower than 30%, preferably higher than or equal to 0% and lower than or equal to 10%.

The CAC-OS is characterized in that a clear peak is not observed when measurement is conducted using a θ/2θ scan by an Out-of-plane method, which is an X-ray diffraction (XRD) measurement method. That is, it is found from X-ray diffraction measurement that no alignment in the a-b plane direction and the c-axis direction is observed in a measured region.

In an electron diffraction pattern of the CAC-OS which is obtained by irradiation with an electron beam with a probe diameter of 1 nm (also referred to as a nanobeam electron beam), a ring-like high-luminance region (ring region) and a plurality of bright spots in the ring region are observed. It is therefore found from the electron diffraction pattern that the crystal structure of the CAC-OS includes an nc (nano-crystal) structure with no alignment in the plan-view direction and the cross-sectional direction.

Moreover, for example, it can be confirmed by EDX mapping obtained using energy dispersive X-ray spectroscopy (EDX) that the CAC-OS in the In—Ga—Zn oxide has a composition in which regions including Gao_{X3} as a main component and regions including In_{X2}Zn_{Y2}O_{Z2} or InO_{X1} as a main component are unevenly distributed and mixed.

The CAC-OS has a composition different from that of an IGZO compound in which metal elements are evenly distributed, and has characteristics different from those of the IGZO compound. That is, in the CAC-OS, regions including Gao_{X3} or the like as a main component and regions including In_{X2}Zn_{Y2}O_{Z2} or InO_{X1} as a main component are phase-separated from each other to form a mosaic pattern.

Here, a region including In_{X2}Zn_{Y2}O_{Z2} or InO_{X1} as a main component has a higher conductivity than a region including Gao_{X3} or the like as a main component. In other words, when carriers flow through the regions including In_{X2}Zn_{Y2}O_{Z2} or InO_{X1} as a main component, the conductivity of an oxide semiconductor is exhibited. Accordingly, when the regions including In_{X2}Zn_{Y2}O_{Z2} or InO_{X1} as a main component are distributed in an oxide semiconductor like a cloud, high field-effect mobility (μ) can be achieved.

By contrast, a region including Gao_{X3} or the like as a main component has a higher insulating property than a region including In_{X2}Zn_{Y2}O_{Z2} or InO_{X1} as a main component. In other words, when the regions including Gao_{X3} or the like as a main component are distributed in an oxide semiconductor, a leakage current can be reduced and a favorable switching operation can be achieved.

Accordingly, when the CAC-OS is used for a semiconductor element, the insulating property derived from Gao_{X3} or the like and the conductivity derived from In_{X2}Zn_{Y2}O_{Z2} or InO_{X1} complement each other, whereby a high on-state current (Ion) and high field-effect mobility (μ) can be achieved.

A semiconductor element using the CAC-OS has high reliability. Thus, the CAC-OS is suitably used as a constituent material of a variety of semiconductor devices.

Next, a stacked-layer structure of the imaging device is described with reference to a cross-sectional view. The cross-sectional view corresponds to a plane in the height direction including the dashed-dotted line A1-A2 illustrated in the layer 24 in FIG. 2. Note that components such as insulating layers and conductive layers that are described below are examples, and the imaging device may further include another component. Alternatively, some of the components described below may be omitted. The stacked-layer structure described below can be formed by repeating a deposition step, a polishing step, and the like as needed.

### <Stacked-Layer Structure 1>

FIG. 17 is a cross-sectional view example of an imaging device employing the layout illustrated in FIG. 4. The transistor 102 and the transistor 103 in the layer 24 are each illustrated as a transistor including a channel formation region in the substrate 441. In addition, the photoelectric conversion device 101 and the capacitor 106 are illustrated in the layer 24. Although not illustrated in FIG. 17, a transistor including a channel formation region in the substrate 441 is preferably used as the structure of each of the transistor 104 and the transistor 105. FIG. 17 illustrates an example in which the transistor including a channel formation region in the substrate 441 is used as the structure of each the transistor 102 and the transistor 103; an OS transistor may be used instead.

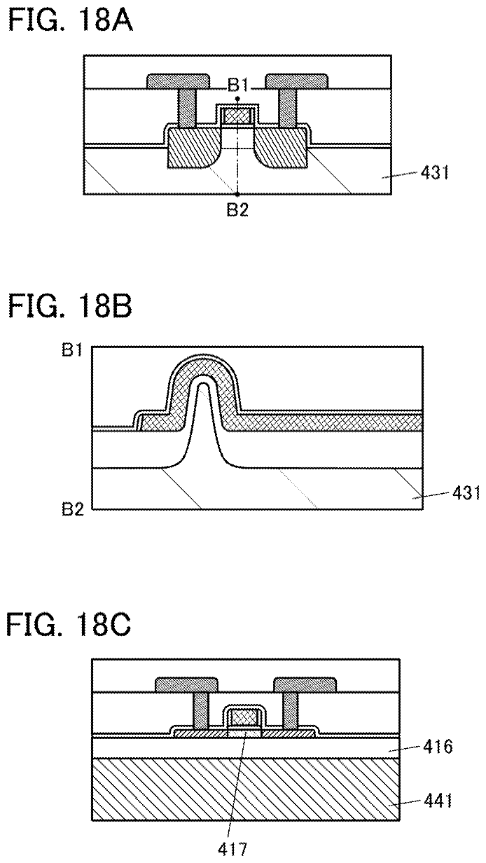

The transistors illustrated in FIG. 17 are planar-type transistors, but may be fin-type transistors as illustrated in FIG. 18A and FIG. 18B. FIG. 18A is a cross-sectional view in the channel length direction, and FIG. 18B is a cross-sectional view of a position of the dashed-dotted line B1-B2 illustrated in FIG. 18A in the channel width direction.

Alternatively, a transistor may include a semiconductor layer 417 of a silicon thin film as illustrated in FIG. 18C. The semiconductor layer 417 can be single crystal silicon (SOI (Silicon on Insulator)) formed on an insulating layer 416 over the substrate 441 included in the layer 24, for example.

The photoelectric conversion device 101 illustrated in the layer 24 has the structure of the pn-junction photodiode illustrated in FIG. 16A and includes a layer 441n (n-type region) and a layer 441p (p-type region, part of the substrate 441).

The photoelectric conversion device 101 included in one pixel is surrounded by the element isolation layer 443 to be separated from the photoelectric conversion device 101 in an adjacent pixel. The element isolation layer 443 can inhibit carriers generated by photoelectric conversion from diffusing into adjacent pixels. Note that the element isolation layer 443 may have a function of a light-blocking layer or a reflective layer.

As the element isolation layer 443, an inorganic insulating layer, an organic insulating layer, or the like can be used. A space may be provided in part of the element isolation layer 443. The space may contain air or a gas such as an inert gas. The space may be in a reduced pressure state.

In the case where the transistor 102 is an n-channel transistor and low-resistance regions functioning as a source and a drain have n-type conductivity in FIG. 17, one of the source and the drain of the transistor 102 and the n-type region of the photoelectric conversion device 101 are used in common. Such a structure allows complete transfer of electric charge due to complete depletion in the photoelectric conversion device 101, thereby reducing noise. A region 441n_2 formed in the substrate 441 functions as the other of the source and the drain of the transistor 102.

The transistor 103 and the transistor 102 each include a gate electrode and a gate insulating layer; in each of the transistors, the gate insulating layer is interposed between the gate electrode and the layer 441p. An electrode 102G functions as the gate electrode of the transistor 102.

In the structure illustrated in FIG. 17, an insulating layer 222 is provided so as to cover the transistor 102, the transistor 103, and the photoelectric conversion device 101; an insulating layer 223 is provided so as to cover the insulating layer 222; and the insulating layer 222 and the insulating layer 223 are positioned between the substrate 441 and the capacitor 106.

The layer 24 includes the capacitor 106. The capacitor 106 includes the wiring 128, the wiring 129, and an insulating layer 226 that is interposed between the wiring 128 and the wiring 129 and functions as a dielectric. In FIG. 17, the capacitor 106 overlaps with the transistor 102, the transistor 103, and the photoelectric conversion device 101.

The wiring 128 and the wiring 121 are provided, for example, in contact with the insulating layer 223. In the structure illustrated in FIG. 17, the wiring 128 is electrically connected to one of the source and the drain of the transistor 103 through a plug provided in the insulating layer 223, and the wiring 121 is electrically connected to the layer 441p through a plug provided in the insulating layer 223 and an insulating layer 242.

In the structure illustrated in FIG. 17, an insulating layer 227 is provided so as to cover the capacitor 106 and the insulating layer 227 is positioned over the insulating layer 412 provided in the layer 21. In the structure illustrated in FIG. 17 or the like, the insulating layer 227 and the insulating layer 412 are preferably bonded to each other.

As the insulating layers included in the layer 24 and the like, for example, an inorganic insulating film such as a silicon oxide film or an organic insulating film of an acrylic resin, a polyimide resin, or the like can be used. Alternatively, a silicon nitride film, a silicon oxide film, an aluminum oxide film, and the like may be stacked.

As a conductor that can be used for a wiring, an electrode, and a plug used for electrical connection between devices, a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements as its component; an alloy containing a combination of the above metal elements; or the like is selected and used as appropriate. The conductor is not limited to a single layer, and may be a plurality of layers including different materials.

The light-blocking layer 451 and an optical conversion layer are provided in the layer 25. Here, the color filter 452G1 is illustrated as the optical conversion layer.

The layer 26 includes the insulating layer 461 and the microlens array 462. Light passing through an individual lens of the microlens array 462 goes through the optical conversion layer directly under the lens, and the photoelectric conversion device 101 is irradiated with the light. With the microlens array 462, collected light can enter the photoelectric conversion device 101; thus, photoelectric conversion can be efficiently performed. The microlens array 462 is preferably formed using a resin, glass, or the like having a high light-transmitting property with respect to light with an intended wavelength.

The light-blocking layer 451 can inhibit light from entering an adjacent pixel. The light-blocking layer 451 can be formed using a material having light-blocking properties, e.g., a material having a light transmittance lower than or equal to 15%. More specifically, it is possible to use, for example, a material whose transmittance of light sensed by the photoelectric conversion device 101 is lower than or equal to 15%. A metal layer of aluminum, tungsten, titanium, tantalum, molybdenum, chromium, copper, or the like can be used as the light-blocking layer 451. Alternatively, the metal layer and a dielectric film may be stacked. The dielectric film functions as an anti-reflection film.

When the photoelectric conversion device 101 has sensitivity to visible light, a color filter can be used as the optical conversion layer. When colors of R (red), G (green), B (blue), Y (yellow), C (cyan), M (magenta), and the like are assigned to the color filters of respective pixels, a color image can be obtained. In this specification and the like, visible light refers to, for example, light with a wavelength longer than or equal to 360 nm and shorter than or equal to 760 nm.

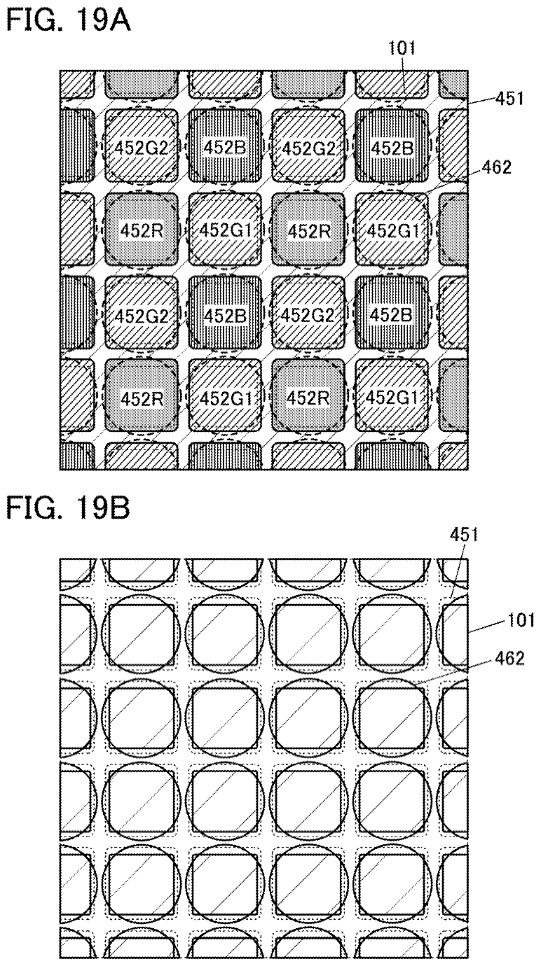

The top view of FIG. 19A illustrates the light-blocking layer 451, a plurality of photoelectric conversion devices 101 arranged in a matrix, the microlens array 462, and an optical conversion layer 452. FIG. 19B is a diagram in which the optical conversion layer 452 is omitted from FIG. 19A for easy viewing of the photoelectric conversion device 101 and the microlens array 462.

In FIG. 19A and FIG. 19B, the light-blocking layer 451 is arranged in a grid and include openings arranged in a matrix. Each of the plurality of photoelectric conversion devices 101 is preferably positioned so as to at least partly overlap with the opening of the light-blocking layer 451.

In FIG. 19A, the color filter 452R (red), the color filter 452G1 (green), the color filter 452G2 (green), and the color filter 452B (blue) are arranged as the optical conversion layers 452 and overlap with the light-blocking layer 451. The color filter 452R, the color filter 452G1, the color filter 452G2, and the color filter 452B can be assigned to the respective pixels, for example. The arrangement of the optical conversion layers illustrated in FIG. 19A is referred to as Bayer arrangement in some cases. In an example of the Bayer arrangement illustrated in FIG. 19A, one red color filter, one blue color filter, and two green color filters are provided; alternatively, two red color filters, one blue color filter, and one green color filter may be provided or one red color filter, two blue color filters, and one green color filter may be provided.

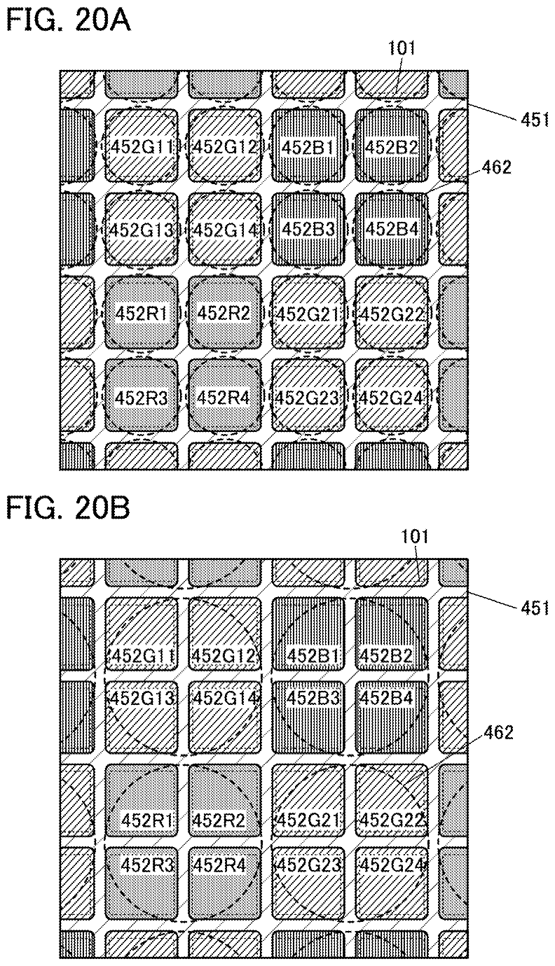

The optical conversion layers may be arranged so that color filters with the same color are assigned to adjacent 2×2 pixels as illustrated in FIG. 20A. The arrangement of the optical conversion layers illustrated in FIG. 20A is referred to as Quad Bayer arrangement in some cases. The Quad Bayer arrangement is an effective way of increasing the dynamic range in a high-definition imaging device. In an example of the arrangement illustrated in FIG. 20A, four pixels with the same color are arranged to be adjacent to each other. When light sensed by the four pixels with the same color is processed as signals of different pixels, a high-definition image can be obtained. Meanwhile, when the adjacent four pixels with the same color are operated as one pixel under low illuminance, the sensitivity and the dynamic range can be increased.

In an example of the Quad Bayer arrangement illustrated in FIG. 20A, the numbers of color filters corresponding to red, blue, and green have a ratio of 1:1:2; alternatively, the numbers of color filters corresponding to red, blue, and green may have a ratio of 2:1:1 or 1:2:1.

In the structures illustrated in FIG. 19A and FIG. 20A, one microlens is provided for each of the photoelectric conversion devices 101; alternatively, one microlens may be provided for 2×2 pixels (four pixels in total) including color filters with the same color as illustrated in FIG. 20B.

In FIG. 19A, FIG. 20A, and FIG. 20B, the light-blocking layer 451 is provided between adjacent color filters, thereby inhibiting light from entering an adjacent pixel to suppress color mixture between the adjacent pixels.

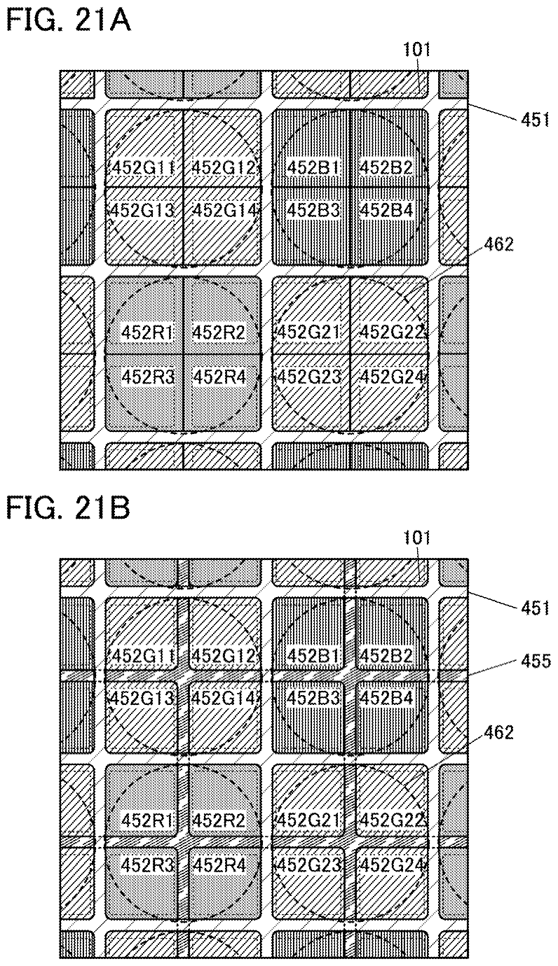

However, in FIG. 20A and FIG. 20B, color mixture is not caused between adjacent color filters with the same color. It is thus possible to employ a structure in which the light-blocking layer 451 is not provided between adjacent color filters with the same color as illustrated in FIG. 21A. The structure in which the light-blocking layer 451 is not provided results in a larger light-receiving area in a pixel. This can further increase the sensitivity and the dynamic range of the imaging device.

On the other hand, electric noise or the like is generated between adjacent pixels in some cases. When a structure in which the transparent conductive layer 455 having light-transmitting properties is provided between adjacent color filters with the same color is employed as illustrated in FIG. 21B, an imaging device with little noise and high sensitivity can be achieved.

As the transparent conductive layer 455, a conductor having light-transmitting properties, e.g., a metal oxide having a visible light transmittance higher than or equal to 70% and lower than or equal to 100%, preferably higher than or equal to 80% and lower than 100%, can be used. As the conductor having light-transmitting properties, indium oxide, tin oxide, zinc oxide, indium-tin oxide, gallium-zinc oxide, indium-gallium-zinc oxide, graphene, or the like can be used.

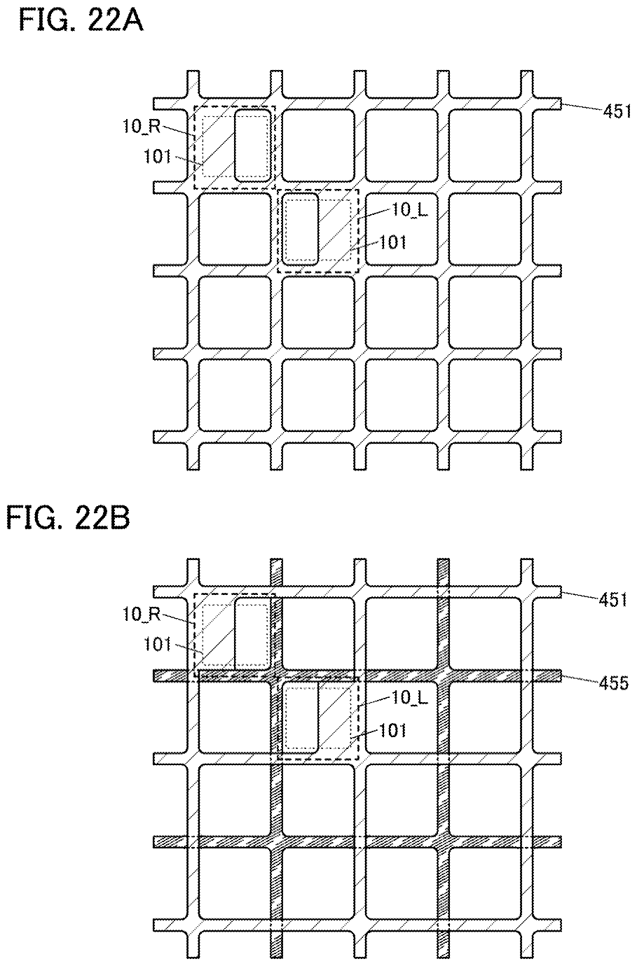

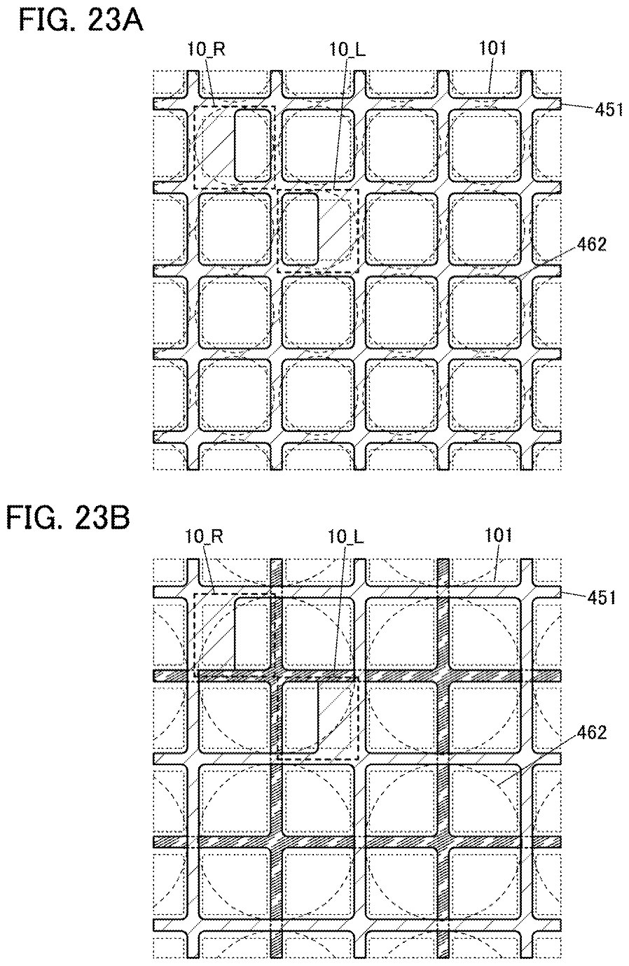

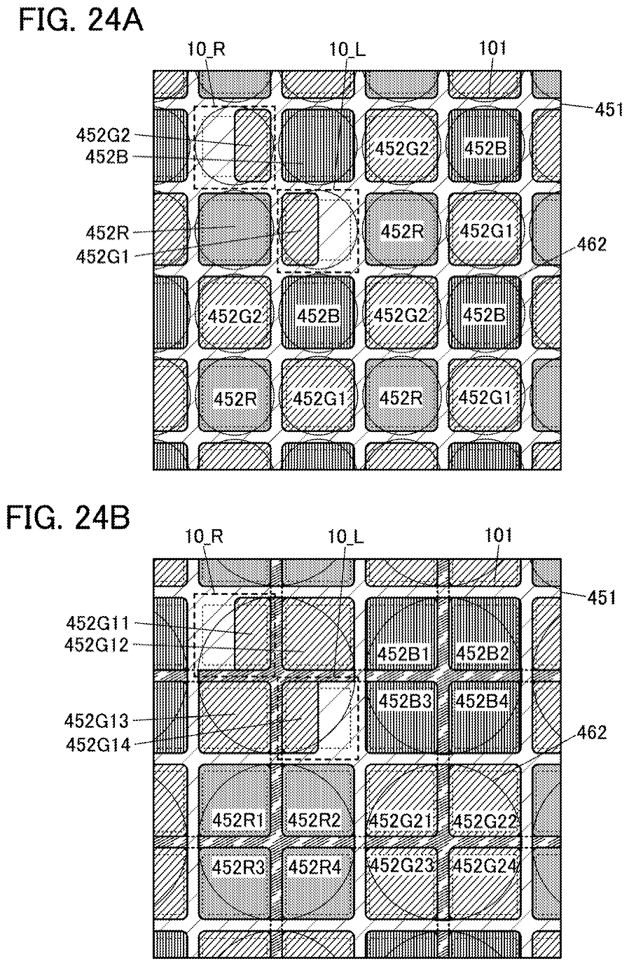

The structure illustrated in FIG. 22A includes the pixel 10 in which almost half of the photoelectric conversion device 101 is covered with the light-blocking layer 451. The pixel 10 having an opening of the light-blocking layer 451 that overlaps with almost left half of the photoelectric conversion device 101 is referred to as a pixel 10_L. In the pixel 10_L, almost right half of the photoelectric conversion device 101 overlaps with the light-blocking layer 451. The pixel 10 having an opening of the light-blocking layer 451 that overlaps with almost right half of the photoelectric conversion device 101 is referred to as a pixel 10_R. In the pixel 10_R, almost left half of the photoelectric conversion device 101 overlaps with the light-blocking layer 451. Note that in the top view of FIG. 22A, the optical conversion layer 452, the microlens array 462, and the like are not illustrated for easy viewing of the drawing; the microlens array 462 is additionally illustrated in FIG. 23A, and the optical conversion layer 452 is further illustrated in FIG. 24A.

FIG. 22B illustrates a structure in which the transparent conductive layer 455 is provided instead of part of the light-blocking layer 451 in FIG. 22A. Note that in the top view of FIG. 22B, the optical conversion layer 452, the microlens array 462, and the like are not illustrated for easy viewing of the drawing; the microlens array 462 is additionally illustrated in FIG. 23B, and the optical conversion layer 452 is further illustrated in FIG. 24B.

In the pixel 10_L, almost left half of a square concentric with the light axis of a microlens overlaps with the opening of the light-blocking layer 451. In the pixel 10_R, almost right half of a square concentric with the light axis of a microlens overlaps with the opening of the light-blocking layer 451. The comparison between the amount of light entering the pixel 10_L and the amount of light entering the pixel 10_R enables the focal point to be sensed by a pupil division phase difference method. Here, the light axis of a microlens is, for example, a straight line that passes through the center of the microlens when seen from the above. The light axis of the microlens is substantially perpendicular to the substrate 441, for example.

Considered is the case where the pixel 10_L and the pixel 10_R include the photoelectric conversion devices 101 having substantially the same shape when seen from the above. In such a case, at least part of the region where the photoelectric conversion device 101 of the pixel 10_L overlaps with the opening of the light-blocking layer 451 corresponds to the region where the photoelectric conversion device 101 of the pixel 10_R does not overlap with the opening of the light-blocking layer 451.

The amount of light entering the pixel 10_L and the amount of light entering the pixel 10_R change with the amount of deviation from the focal point (the defocus amount) in image formation.

Considered as an example is the case where a shooting lens is placed in front of the microlens that is adjusted back-and-forth to be focused. With the focal point as a reference, the shooting lens is shifted forward in some cases (forward defocusing state) and is shifted backward in other cases (backward defocusing state). In the imaging device of one embodiment of the present invention, the amount of light entering the pixel 10_L increases in one of the defocusing states and decreases in the other of the defocusing states. The amount of light entering the pixel 10_R decreases in the one defocusing state, i.e., in the state where the amount of light entering the pixel 10_L increases; while the amount of light entering the pixel 10_R increases in the other defocusing state, i.e., in the state where the amount of light entering the pixel 10_L decreases.

Thus, the amount of deviation from the focal point can be measured by analyzing a change in the amount of light entering the pixel 10_L and a change in the amount of light entering the pixel 10_R. Although the focal point is sensed here by comparison between the amounts of light in almost left half of a pixel and almost right half of the pixel, it may be sensed by comparison between almost upper half of the pixel and almost lower half of the pixel. A light-blocking region and an opening can have any other shapes as long as two openings are provided in pixels so that light entering the photoelectric conversion device is brought into the two defocusing states of the focal point.

In the case where the pixel 10_L is divided, in a top view, into two regions (hereinafter referred to as a third region and a fourth region) along the light axis of the microlens (hereinafter referred to as a first microlens) overlapping with the pixel 10_L or along a first straight line that passes through the center of the microlens, the light-blocking layer 451 preferably overlaps with less than 30%, further preferably less than 20% of the third region. In addition, the light-blocking layer 451 preferably overlaps with 60% or more, further preferably 70% or more, and still further preferably 80% or more of the fourth region. Here, on the assumption that the direction perpendicular to the first straight line is the x axis, the fourth region is positioned in a region that has a larger x-coordinate than the third region.

The opening of the light-blocking layer 451 preferably overlaps with 70% or more, further preferably 80% or more of the third region.

In the case where the pixel 10_R is divided, in a top view, into two regions (hereinafter referred to as a fifth region and a sixth region) along the light axis of the microlens (hereinafter referred to as a second microlens) overlapping with the pixel 10_R or along a second straight line that passes through the center of the microlens, the light-blocking layer 451 preferably overlaps with 70% or more, further preferably 80% or more of the fifth region. In addition, the light-blocking layer 451 preferably overlaps with less than 40%, further preferably less than 30%, and still further preferably less than 20% of the sixth region. Here, it is assumed that the second straight line is perpendicular to the x axis. The sixth region is positioned in a region that has a larger x-coordinate than the fifth region.

The opening of the light-blocking layer 451 preferably overlaps with 60% or more, further preferably 70% or more, and still further preferably 80% or more of the sixth region.

In the case where the x axis is the horizontal direction in the top view, the fourth region is positioned on the right side of the third region. That is, in the case where the pixel 10_L is divided into left and right regions along the first straight line, the light-blocking layer 451 preferably overlaps with less than 40%, further preferably less than 30%, and still further preferably less than 20% of the left region, and preferably overlaps with 70% or more, further preferably 80% or more of the right region. The opening of the light-blocking layer 451 preferably overlaps with 60% or more, further preferably 70% or more, and still further preferably 80% or more of the left region, for example.

In the case where the x axis is the horizontal direction in the top view, the sixth region is positioned on the right side of the fifth region. That is, in the case where the pixel 10_R is divided into left and right regions along the second straight line, the light-blocking layer 451 preferably overlaps with 70% or more, further preferably 80% or more of the left region, and preferably overlaps with less than 40%, further preferably less than 30%, and still further preferably less than 20% of the right region. The opening of the light-blocking layer 451 preferably overlaps with 60% or more, further preferably 70% or more, and still further preferably 80% or more of the right region, for example.

In the example illustrated in FIG. 24B, color filters corresponding to green are used in the pixel 10_L and the pixel 10_R; however, the color filters are not necessarily provided in the pixel 10_L and the pixel 10_R. The structure without color filters can increase the amount of light, thereby shortening the time taken for focal point sensing.

When a wavelength cut filter is used as the optical conversion layer 452, the imaging device can capture images in various wavelength regions.

For example, when an infrared filter that blocks light with a wavelength shorter than or equal to that of visible light is used as the optical conversion layer 452, an infrared imaging device can be obtained. When a filter that blocks light with a wavelength shorter than or equal to that of near infrared light is used as the optical conversion layer 452, a far-infrared imaging device can be obtained. When an ultraviolet filter that blocks light with a wavelength longer than or equal to that of visible light is used as the optical conversion layer 452, an ultraviolet imaging device can be obtained.

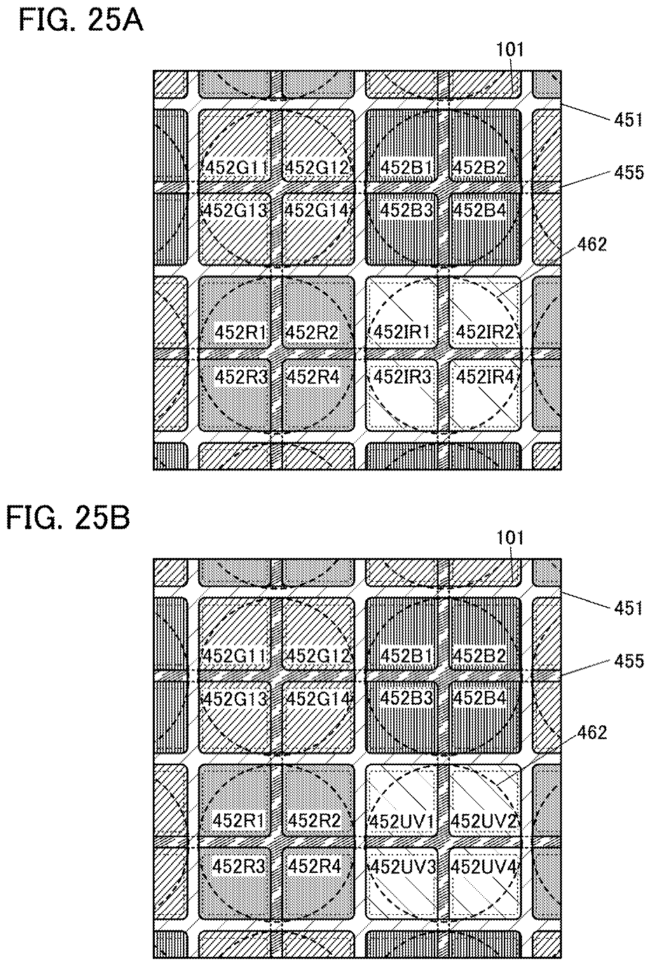

Note that optical conversion layers with different functions may be provided in one imaging device. For example, filters corresponding to red, green, blue, and infrared can be assigned to the respective pixels. FIG. 25A illustrates an example in which the color filter 452R (red), the color filter 452G1 (green), the color filter 452B (blue), and an infrared filter 45218 are assigned to the respective pixels in the Quad Bayer arrangement. With this structure, a visible light image and an infrared light image can be obtained simultaneously. [0258]

Alternatively, filters corresponding to red, green, blue, and ultraviolet can be assigned to the respective pixels. FIG. 25B illustrates an example in which the color filter 452R (red), the color filter 452G1 (green), the color filter 452B (blue), and an ultraviolet filter 452UV are assigned to the respective pixels in the Quad Bayer arrangement. With this structure, a visible light image and an ultraviolet light image can be obtained simultaneously.

When a scintillator is used for the optical conversion layer 452, it is possible to achieve an imaging device that obtains an image visualizing the intensity of radiation, which is used for an X-ray imaging device or the like. Radiation such as X-rays passes through an object and enters the scintillator, and then is converted into light (fluorescence) such as visible light or ultraviolet light owing to a photoluminescence phenomenon. Then, the photoelectric conversion device 101 detects the light to obtain image data. Furthermore, the imaging device having this structure may be used in a radiation detector or the like.

A scintillator contains a substance that, when irradiated with radiation such as X-rays or gamma-rays, absorbs energy of the radiation to emit visible light or ultraviolet light. For example, it is possible to use a resin or ceramics in which Gd₂O₂S:Tb, Gd₂O₂S:Pr, Gd₂O₂S:Eu, BaFC₁:Eu, NaI, CsI, CaF₂, BaF₂, CeF₃, LiF, LiI, ZnO, or the like is dispersed.

Image capturing with the use of infrared light or ultraviolet light can provide the imaging device with an inspection function, a security function, a sensor function, or the like. For example, by image capturing with the use of infrared light, non-destructive inspection of products, sorting of agricultural products (e.g., sugar content meter function), vein authentication, medical inspection, or the like can be performed. Furthermore, by image capturing with the use of ultraviolet light, ultraviolet light released from a light source or a frame can be sensed, whereby a light source, a heat source, a production device, or the like can be controlled, for example.

### <Stacked-Layer Structure 2>

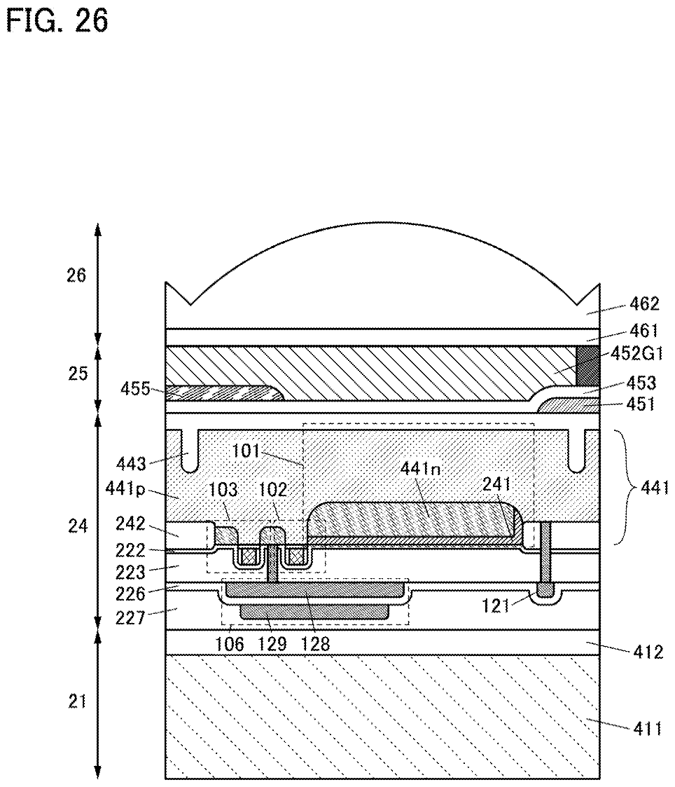

FIG. 26 is a cross-sectional view corresponding to a structure in which part of the light-blocking layer 451 illustrated in FIG. 21B, FIG. 25, and the like is replaced with the transparent conductive layer 455. In the structure illustrated in FIG. 26, an insulating layer 453 is provided over the light-blocking layer 451, and the transparent conductive layer 455 is provided over the insulating layer 453.

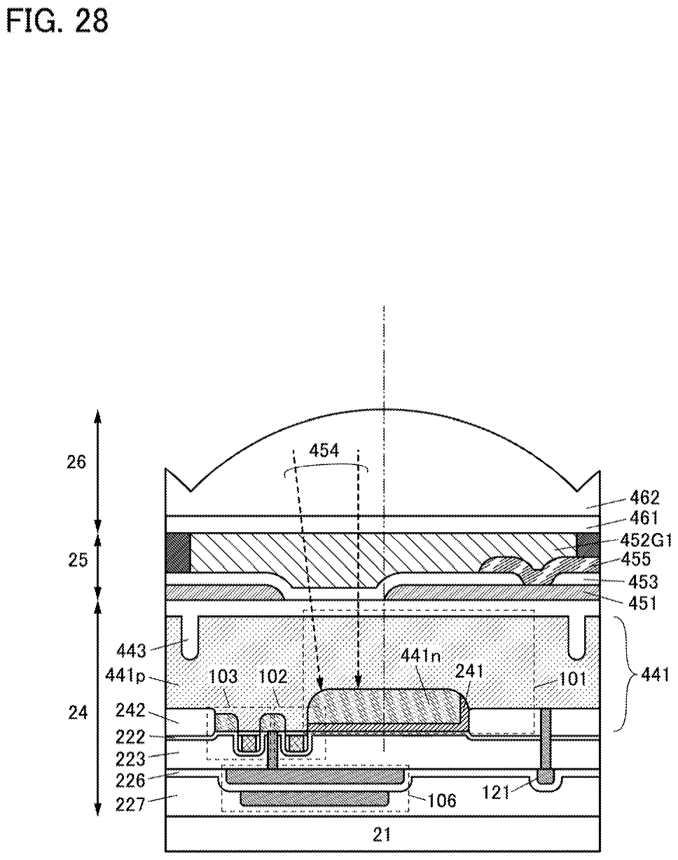

An opening is provided in the insulating layer 453 so that the transparent conductive layer 455 can be electrically connected to the light-blocking layer 451. FIG. 28 and the like described later show that an opening of the insulating layer 453 is provided over the light-blocking layer 451, and the transparent conductive layer 455 is formed to be embedded in the opening so that the light-blocking layer 451 is in contact with the transparent conductive layer 455.

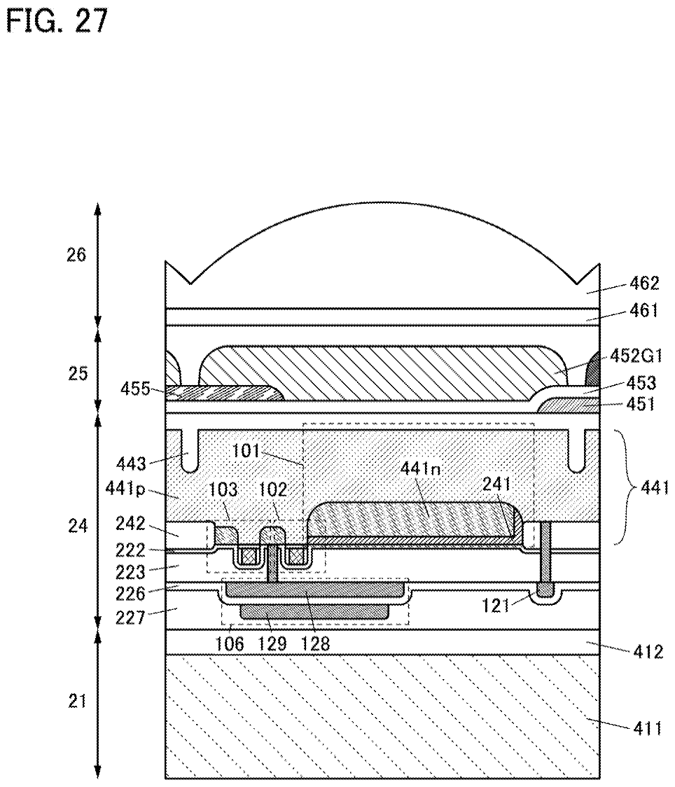

As illustrated in FIG. 27, adjacent color filters may be spaced from each other and a resin may be provided between the adjacent color filters. The resin is provided over the transparent conductive layer 455, for example. Alternatively, the resin may be in contact with the top surface of the transparent conductive layer 455. In FIG. 27, the color filter is covered with a resin or the like, for example.

Alternatively, a space may be provided between the adjacent color filters.

The resin provided between the adjacent color filters is in contact with the top surface of the light-blocking layer 451 in some cases.

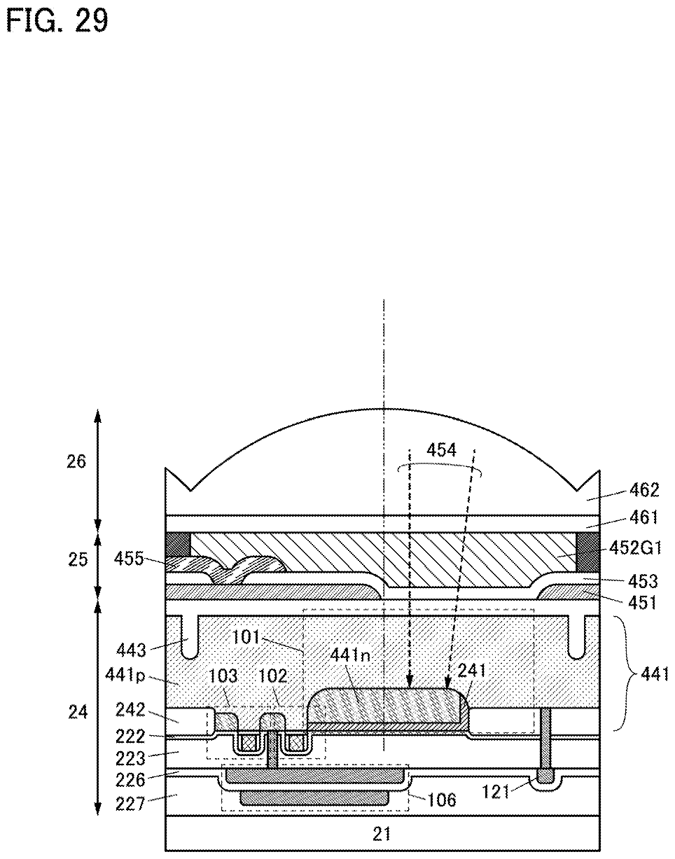

FIG. 28 illustrates an example of a cross-sectional structure that can be applied to the pixel 10_L. FIG. 29 illustrates an example of a cross-sectional structure that can be applied to the pixel 10_R.

In FIG. 28, the light-blocking layer 451 has an opening that overlaps with almost left half of the photoelectric conversion device 101. The light-blocking layer 451 has a function of blocking light entering almost right half of the photoelectric conversion device 101. In the microlens array 462, a luminous flux entering the left half of the lens in a luminous flux 454 entering the microlens overlapping with the photoelectric conversion device 101 enters the photoelectric conversion device 101.

In FIG. 29, the light-blocking layer 451 has an opening that overlaps with almost right half of the photoelectric conversion device 101. The light-blocking layer 451 has a function of blocking light entering almost left half of the photoelectric conversion device 101. In the microlens array 462, a luminous flux entering the right half of the lens in the luminous flux 454 entering the microlens overlapping with the photoelectric conversion device 101 enters the photoelectric conversion device 101.

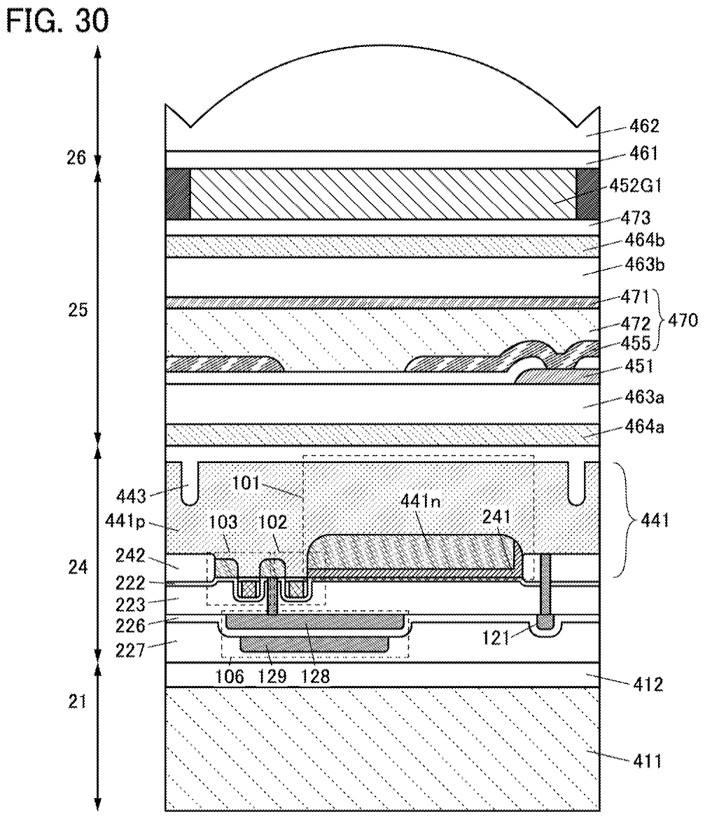

FIG. 30 illustrates an example in which the layer 25 includes a liquid crystal element 470. The liquid crystal element 470 illustrated in FIG. 30 includes the transparent conductive layer 455, a transparent conductive layer 471, and a liquid crystal layer 472. In FIG. 30, a substrate 463a and a polarizing plate 464a are provided between the liquid crystal element 470 and the substrate 441, and a substrate 463b and a polarizing plate 464b are provided between the liquid crystal element 470 and the microlens array 462. An insulating layer 473 may be provided between the liquid crystal element 470 and the optical conversion layer 452.

The transmittance of the liquid crystal element 470 can be controlled by controlling the electric field applied to the liquid crystal element 470. When the transmittance of the liquid crystal element 470 is reduced by controlling the electric field applied thereto, the liquid crystal element 470 can function as a light-blocking layer. For example, only when the imaging device senses a focal point, an electric signal is supplied to the liquid crystal element 470 so that only the half of the photoelectric conversion device 101 is light-shielded, and the transmittance is increased when focal point sensing is not performed; then, the sensitivity of the pixel can be increased in the case where focal point sensing is not performed.

As the liquid crystal element, for example, a liquid crystal element employing a vertical alignment (VA) mode can be used. As the vertical alignment mode, an MVA (Multi-Domain Vertical Alignment) mode, a PVA (Patterned Vertical Alignment) mode, an ASV (Advanced Super View) mode, and the like can be used.

As the liquid crystal element, a liquid crystal element employing any of a variety of modes can be used. For example, it is possible to use a liquid crystal element employing a TN (Twisted Nematic) mode, an IPS (In-Plane-Switching) mode, an FFS (Fringe Field Switching) mode, an ASM (Axially Symmetric aligned Micro-cell) mode, an OCB (Optically Compensated Birefringence) mode, an FLC (Ferroelectric Liquid Crystal) mode, an AFLC (AntiFerroelectric Liquid Crystal) mode, an ECB (Electrically Controlled Birefringence) mode, a guest-host mode, or the like instead of a VA mode.

Note that the liquid crystal element is an element that controls the transmission or non-transmission of light utilizing an optical modulation action of a liquid crystal. The optical modulation action of the liquid crystal is controlled by an electric field applied to the liquid crystal (including a horizontal electric field, a vertical electric field, or an oblique electric field). As the liquid crystal used for the liquid crystal element, a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, an anti-ferroelectric liquid crystal, or the like can be used. Such a liquid crystal material exhibits a cholesteric phase, a smectic phase, a cubic phase, a chiral nematic phase, an isotropic phase, or the like depending on conditions.

As the liquid crystal material, either a positive liquid crystal or a negative liquid crystal may be used, and an optimal liquid crystal material can be used depending on the mode or design to be used.

An alignment film can be provided to control the alignment of a liquid crystal. In the case where a horizontal electric field mode is employed, a liquid crystal exhibiting a blue phase for which an alignment film is not used may be used. The blue phase is one of liquid crystal phases, which is generated just before a cholesteric phase changes into an isotropic phase while the temperature of a cholesteric liquid crystal is increased. Since the blue phase appears only in a narrow temperature range, a liquid crystal composition in which a chiral material is mixed to account for several weight percent or more is used for the liquid crystal layer in order to improve the temperature range. The liquid crystal composition containing a liquid crystal exhibiting a blue phase and a chiral material has a short response time and optical isotropy. In addition, the liquid crystal composition containing a liquid crystal exhibiting a blue phase and a chiral material does not need alignment treatment and has small viewing angle dependence. An alignment film does not need to be provided and rubbing treatment is thus not necessary; accordingly, electrostatic discharge damage caused by the rubbing treatment can be prevented and defects and damage of the liquid crystal display device in the manufacturing process can be reduced.

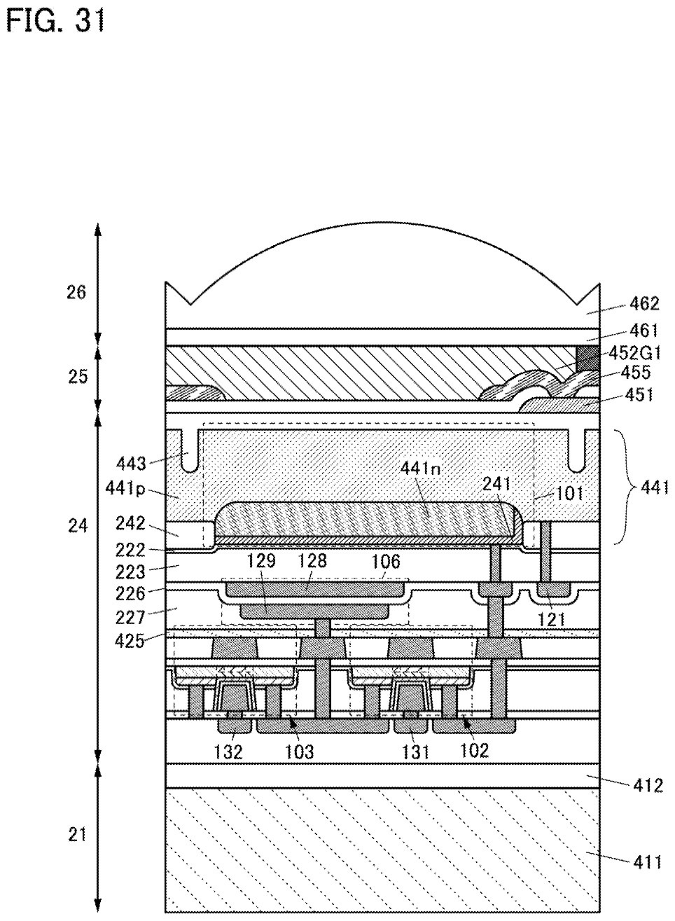

FIG. 31 illustrates an example of a structure in which an OS transistor is used as the transistor 102 and the transistor 103. In FIG. 31, the transistor 102 and the transistor 103 are provided so as to overlap with the photoelectric conversion device 101, and the capacitor 106 is provided between the photoelectric conversion device 101, and the transistor 102 and the transistor 103. Note that the transistor 102 and the transistor 103 may be provided between the photoelectric conversion device 101 and the capacitor 106.

The transistor 102 and the transistor 103 are positioned in a deeper region than the photoelectric conversion device 101 when seen from a surface of the substrate 441 that is irradiated with light. This can reduce the effect of light irradiation on the transistor 102 and the transistor 103. Thus, the light-blocking layer 451 is not necessarily provided in some cases. Instead of the light-blocking layer 451, the transparent conductive layer 455 can be provided in some cases.

Although not illustrated in FIG. 31, the substrate 441 can be provided with a transistor such as the transistor 104 or the transistor 105, a capacitor, and the like.

In FIG. 31, an insulating layer 425 is provided between the transistor 102 and the transistor 103, and a semiconductor element such as a transistor provided for the substrate 441.

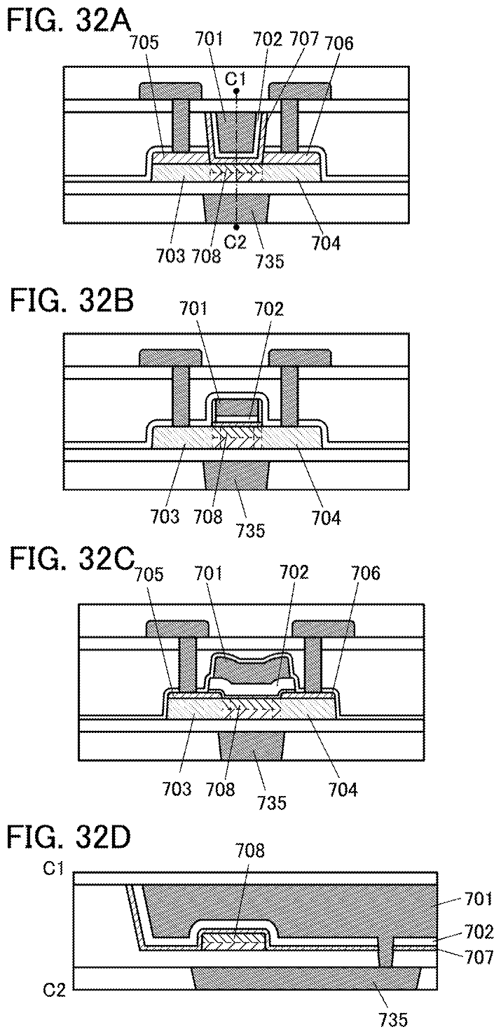

FIG. 32A to FIG. 32D illustrate structure examples of an OS transistor that can be applied to the transistor of one embodiment of the present invention.

The OS transistor illustrated in FIG. 32A has a self-aligned structure in which a source electrode 705 and a drain electrode 706 are formed through formation of an insulating layer over a stack of an oxide semiconductor layer and a conductive layer and formation of an opening reaching the oxide semiconductor layer.

The OS transistor can include a gate electrode 701 and a gate insulating film 702 in addition to a channel formation region 708, a source region 703, and a drain region 704 that are formed in the oxide semiconductor layer. At least the gate insulating film 702 and the gate electrode 701 are provided in the opening. An oxide semiconductor layer 707 may also be provided in the opening.

As illustrated in FIG. 32B, the OS transistor may have a self-aligned structure in which the source region 703 and the drain region 704 are formed in the semiconductor layer with the gate electrode 701 as a mask.

As illustrated in FIG. 32C, the OS transistor may be a non-self-aligned top-gate transistor including a region where the gate electrode 701 overlaps with the source electrode 705 or the drain electrode 706.

Although the OS transistor has a structure with a back gate 735, it may have a structure without a back gate. As illustrated in a cross-sectional view of the transistor in the channel width direction in FIG. 32D, the back gate 735 may be electrically connected to a front gate of the transistor, which is provided to face the back gate. Note that FIG. 32D illustrates a C1-C2 cross section of the transistor in FIG. 32A as an example, and the same applies to a transistor having any of the other structures. A structure in which different fixed potentials can be supplied to the back gate 735 and the front gate may be employed.

An insulating layer 425 is preferably provided between the layer in which the OS transistors are provided and the layer in which the Si transistors are provided. The insulating layer 425 functions as a blocking layer.

As the blocking layer, a film that has a function of preventing hydrogen diffusion is preferably used. In a Si device, hydrogen is necessary to terminate dangling bonds; however, hydrogen in the vicinity of an OS transistor is one of factors of generating carriers in an oxide semiconductor layer, which leads to a decrease in reliability. Therefore, a hydrogen blocking film is preferably provided between a layer in which the Si device is formed and a layer in which the OS transistor is formed.

For the blocking film, for example, aluminum oxide, aluminum oxynitride, gallium oxide, gallium oxynitride, yttrium oxide, yttrium oxynitride, hafnium oxide, hafnium oxynitride, or yttria-stabilized zirconia (YSZ) can be used.

### <Package and Module>

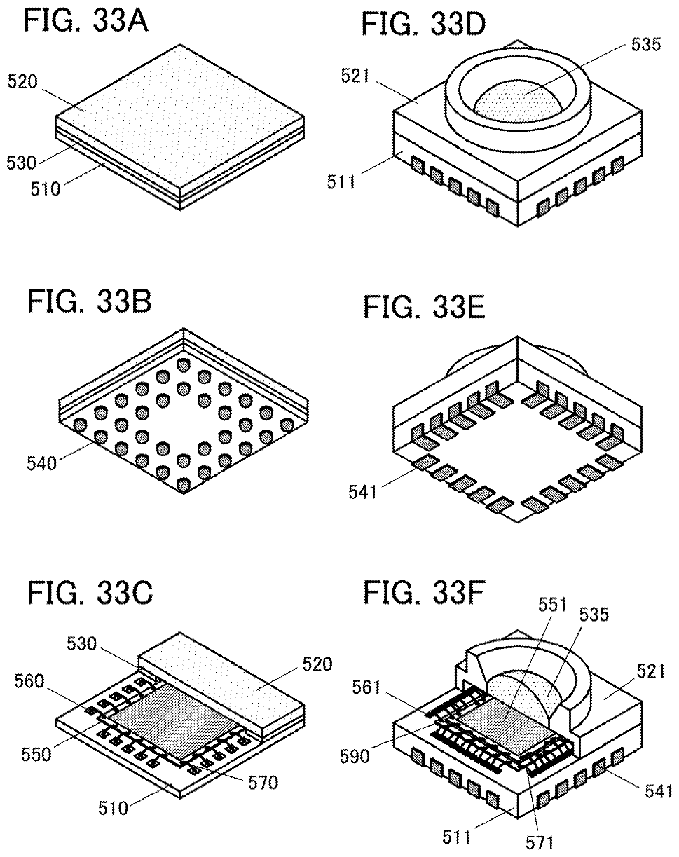

FIG. 33A is an external perspective view of the top surface side of a package in which an image sensor chip is placed. The package includes a package substrate 510 to which an image sensor chip 550 (see FIG. 33C) is fixed, a cover glass 520, an adhesive 530 for bonding them, and the like.

FIG. 33B is an external perspective view of the bottom surface side of the package. The bottom surface of the package includes a BGA (Ball grid array) in which solder balls are used as bumps 540. Without being limited to the BGA, an LGA (Land grid array), a PGA (Pin Grid Array), or the like may be employed.

FIG. 33C is a perspective view of the package, in which parts of the cover glass 520 and the adhesive 530 are not illustrated. Electrode pads 560 are formed over the package substrate 510, and the electrode pads 560 and the bumps 540 are electrically connected to each other via through-holes. The electrode pads 560 are electrically connected to the image sensor chip 550 through wires 570.

FIG. 33D is an external perspective view of the top surface side of a camera module in which an image sensor chip is placed in a package with a built-in lens. The camera module includes a package substrate 511 to which an image sensor chip 551 (see FIG. 33F) is fixed, a lens cover 521, a lens 535, and the like. An IC chip 590 (see FIG. 33F) having functions of a driver circuit, a signal conversion circuit, and the like of an imaging device is provided between the package substrate 511 and the image sensor chip 551; thus, the structure as an SiP (System in package) is included.

FIG. 33E is an external perspective view of the bottom surface side of the camera module. A QFN (Quad flat no-lead package) structure in which lands 541 for mounting are provided on the bottom surface and side surfaces of the package substrate 511 is employed. Note that this structure is only an example, and a QFP (Quad flat package) or the above-mentioned BGA may also be provided.

FIG. 33F is a perspective view of the module, in which parts of the lens cover 521 and the lens 535 are not illustrated. The lands 541 are electrically connected to electrode pads 561, and the electrode pads 561 are electrically connected to the image sensor chip 551 or the IC chip 590 through wires 571.

The image sensor chip placed in a package having the above form can be easily mounted on a printed circuit board and the like; hence, the image sensor chip can be incorporated into a variety of semiconductor devices and electronic devices.

This embodiment can be combined with the description of the other embodiments as appropriate.

### Embodiment 4

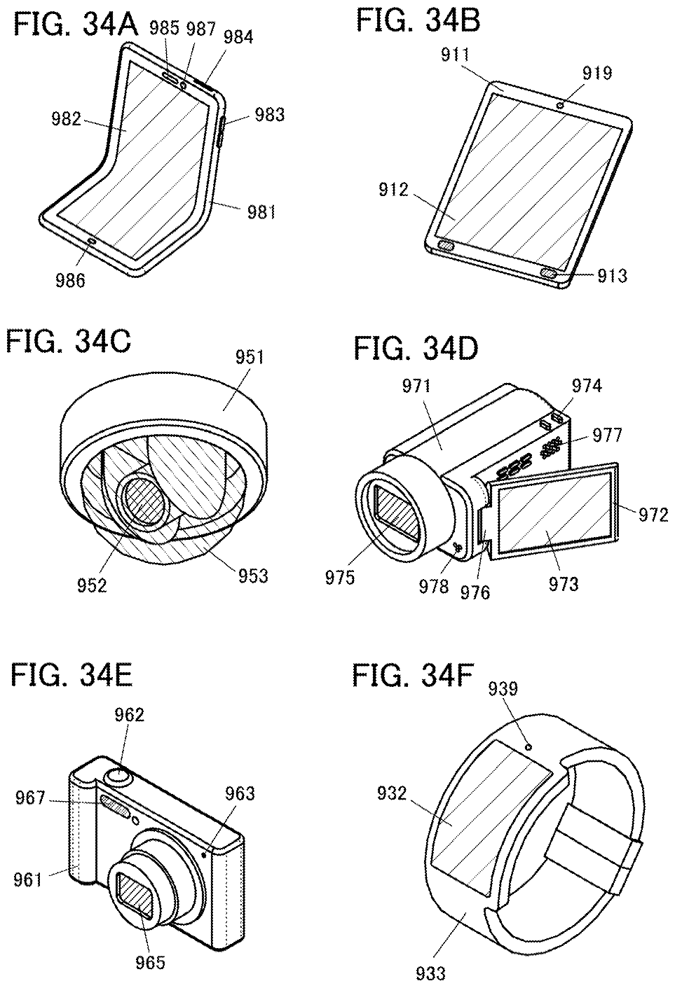

As electronic devices that can use the imaging device of one embodiment of the present invention, display apparatuses, personal computers, image memory devices or image reproducing devices provided with storage media, mobile phones, game machines including portable game machines, portable data terminals, e-book readers, cameras such as video cameras and digital still cameras, goggle-type displays (head mounted displays), navigation systems, audio reproducing devices (car audio players, digital audio players, and the like), copiers, facsimiles, printers, multifunction printers, automated teller machines (ATM), vending machines, and the like are given. FIG. 34A to FIG. 34F illustrate specific examples of these electronic devices.

FIG. 34A is an example of a mobile phone, which includes a housing 981, a display portion 982, an operation button 983, an external connection port 984, a speaker 985, a microphone 986, a camera 987, and the like. The display portion 982 of the mobile phone is provided with a touch sensor. A variety of operations such as making a call and inputting text can be performed by touch on the display portion 982 with a finger, a stylus, or the like. The imaging device of one embodiment of the present invention and the operation method thereof can be used in the mobile phone, enabling an infrared light image as well as a color image to be obtained.

FIG. 34B is a portable data terminal, which includes a housing 911, a display portion 912, a speaker 913, a camera 919, and the like. A touch panel function of the display portion 912 enables input and output of information. Furthermore, a character or the like in an image that is captured by the camera 919 can be recognized and the character can be voice-output from the speaker 913. The imaging device of one embodiment of the present invention and the operation method thereof can be used in the portable data terminal, enabling an infrared light image as well as a color image to be obtained.

FIG. 34C is a surveillance camera, which includes a support base 951, a camera unit 952, a protection cover 953, and the like. By setting the camera unit 952 provided with a rotating mechanism and the like on a ceiling, an image of all of the surroundings can be taken. The imaging device of one embodiment of the present invention and the operation method thereof can be used for obtaining an image in the camera unit, enabling an infrared light image as well as a color image to be obtained. Note that a surveillance camera is a name in common use and does not limit the use thereof. A device that has a function of a surveillance camera can also be called a camera or a video camera, for example.

FIG. 34D is a video camera, which includes a first housing 971, a second housing 972, a display portion 973, an operation key 974, a lens 975, a connection portion 976, a speaker 977, a microphone 978, and the like. The operation key 974 and the lens 975 are provided for the first housing 971, and the display portion 973 is provided for the second housing 972. The imaging device of one embodiment of the present invention and the operation method thereof can be used in the video camera, enabling an infrared light image as well as a color image to be obtained.

FIG. 34E is a digital camera, which includes a housing 961, a shutter button 962, a microphone 963, a light-emitting portion 967, a lens 965, and the like. The imaging device of one embodiment of the present invention and the operation method thereof can be used in the digital camera, enabling an infrared light image as well as a color image to be obtained.

FIG. 34F is a wrist-watch-type information terminal, which includes a display portion 932, a housing and wristband 933, a camera 939, and the like. The display portion 932 is provided with a touch panel for performing the operation of the information terminal. The display portion 932 and the housing and wristband 933 have flexibility and fit a body well. The imaging device of one embodiment of the present invention and the operation method thereof can be used in the information terminal, enabling an infrared light image as well as a color image to be obtained.

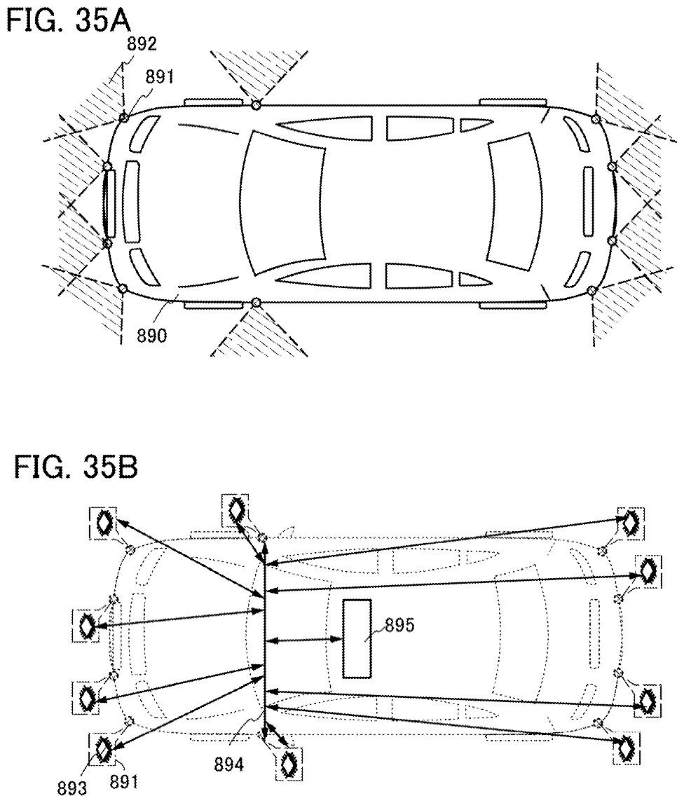

FIG. 35A illustrates an external diagram of an automobile as an example of a moving object. FIG. 35B is a simplified diagram illustrating data transmission in the automobile. An automobile 890 includes a plurality of cameras 891 and the like. The imaging device of one embodiment of the present invention and the operation method thereof can be used in the cameras 891. The automobile 890 is also provided with various sensors such as an infrared radar, a millimeter wave radar, and a laser radar (not illustrated) and the like.

In the automobile 890, an integrated circuit 893 can be used for the camera 891 and the like. The automobile 890 judges traffic conditions therearound such as the presence of a guardrail or a pedestrian by processing a plurality of images in a plurality of image capturing directions 892 taken by the cameras 891 with the integrated circuits 893 and collectively analyzing the plurality of images with a host controller 895 or the like through a bus 894 or the like, and thus can perform autonomous driving. The integrated circuit 893 can be used for a system for navigation, risk prediction, or the like.

When arithmetic processing of a neural network or the like is performed on the obtained image data by the integrated circuit 893, for example, processing for the following can be performed: an increase in image resolution, a reduction in image noise, face recognition (for security reasons or the like), object recognition (for autonomous driving or the like), image compression, image compensation (a wide dynamic range), restoration of an image of a lensless image sensor, positioning, character recognition, and a reduction of glare and reflection.

Note that an automobile is described above as an example of a moving object and may be any of an automobile having an internal-combustion engine, an electric vehicle, a hydrogen vehicle, and the like. Furthermore, the moving object is not limited to an automobile. Examples of moving objects include a train, a monorail train, a ship, and a flying object (a helicopter, an unmanned aircraft (a drone), an airplane, and a rocket), and these moving objects can include a system utilizing artificial intelligence when equipped with the computer of one embodiment of the present invention.

This embodiment can be combined with the description of the other embodiments as appropriate.

### REFERENCE NUMERALS

10: pixel, 10_L: pixel, 10_R: pixel, 21: layer, 24: layer, 25: layer, 26: layer, 31: pixel array, 32: circuit, 33: circuit, 34: circuit, 35: circuit, 36: circuit, 38: circuit, 100: pixel, 101: photoelectric conversion device, 101C: photoelectric conversion device, 101D: photoelectric conversion device, 102: transistor, 102G: electrode, 103: transistor, 104: transistor, 105: transistor, 106: capacitor, 107: transistor, 108: transistor, 121: wiring, 122: wiring, 123: wiring, 124: wiring, 125: wiring, 127: wiring, 128: wiring, 129: wiring, 131: wiring, 132: wiring, 133: wiring, 133_1: wiring, 133_2: wiring, 133_3: wiring, 134: wiring, 135: wiring, 135_1: wiring, 135_2: wiring, 135_3: wiring, 142: gate electrode, 143: gate electrode, 144: gate electrode, 145: gate electrode, 161: transistor, 162: transistor, 163: capacitor, 200: pixel block, 201: circuit, 202: capacitor, 203: transistor, 204: transistor, 205: transistor, 206: transistor, 207: transistor, 211: wiring, 212: wiring, 213: wiring, 215: wiring, 216: wiring, 217: wiring, 218: wiring, 219: wiring, 222: insulating layer, 223: insulating layer, 226: insulating layer, 227: insulating layer, 242: insulating layer, 300: pixel array, 301: circuit, 302: circuit, 303: circuit, 304: circuit, 305: circuit, 311: wiring, 320: memory cell, 325: reference memory cell, 330: circuit, 350: circuit, 360: circuit, 370: circuit, 411: substrate, 412: insulating layer, 416: insulating layer, 417: semiconductor layer, 425: insulating layer, 441: substrate, 441n: layer, 441n_2: region, 441p: layer, 443: element isolation layer, 451: light-blocking layer, 452: optical conversion layer, 452B: color filter, 452G1: color filter, 452G2: color filter, 4521R: infrared filter, 452R: color filter, 452UV: ultraviolet filter, 453: insulating layer, 454: luminous flux, 455: transparent conductive layer, 461: insulating layer, 462: microlens array, 463a: substrate, 463b: substrate, 464a: polarizing plate, 464b: polarizing plate, 470: liquid crystal element, 471: transparent conductive layer, 472: liquid crystal layer, 473: insulating layer, 510: package substrate, 511: package substrate, 520: cover glass, 521: lens cover, 530: adhesive, 535: lens, 540: bump, 541: land, 550: image sensor chip, 551: image sensor chip, 560: electrode pad, 561: electrode pad, 565a: layer, 565b: layer, 565c: layer, 570: wire, 571: wire, 590: IC chip, 701: gate electrode, 702: gate insulating film, 703: source region, 704: drain region, 705: source electrode, 706: drain electrode, 707: oxide semiconductor layer, 708: channel formation region, 735: back gate, 890: automobile, 891: camera, 892: image capturing direction, 893: integrated circuit, 894: bus, 895: host controller, 901: circuit portion, 911: housing, 912: display portion, 913: speaker, 919: camera, 932: display portion, 933: housing and wristband, 939: camera, 951: support base, 952: camera unit, 953: protection cover, 961: housing, 962: shutter button, 963: microphone, 965: lens, 967: light-emitting portion, 971: housing, 972: housing, 973: display portion, 974: operation key, 975: lens, 976: connection portion, 977: speaker, 978: microphone, 981: housing, 982: display portion, 983: operation button, 984: external connection port, 985: speaker, 986: microphone, 987: camera

1. An imaging device comprising:
a pixel array comprising n pixels (n is a natural number of 4 or more); and
a light-blocking layer and a transparent conductive layer positioned over the pixel array,
wherein each of the n pixels includes a photoelectric conversion device,
wherein the light-blocking layer includes a first region overlapping with a first pixel and a second region overlapping with a second pixel,
wherein the transparent conductive layer includes a region overlapping with the first region and a region overlapping with the second region,
wherein the transparent conductive layer is electrically connected to the first region and the second region,
wherein first light enters the photoelectric conversion device included in the first pixel,
wherein second light enters the photoelectric conversion device included in the second pixel, and
wherein the imaging device is configured to perform processing with use of a first electric signal generated by conversion of the first light and a second electric signal generated by conversion of the second light.

2. The imaging device according to claim 1,
wherein the imaging device is configured to sense a focal point in image formation with use of the first electric signal generated by conversion of the first light and the second electric signal generated by conversion of the second light.

3. The imaging device according to claim 1,
wherein the transparent conductive layer includes a region overlapping with two or more of a third pixel to an n-th pixel.

4. The imaging device according to claim 1,
wherein the transparent conductive layer includes a plurality of openings in line,
wherein each of the plurality of openings overlaps with one or more of the third pixel to the n-th pixel, and
wherein the plurality of openings are positioned so as to form a grid shape.

5. The imaging device according to claim 4, comprising:
a microlens array comprising m microlenses (m is a natural number of (n−1) or less),
wherein a first microlens overlaps with the first pixel,
wherein a second microlens overlaps with the second pixel,
wherein in the case where the first pixel is divided, in a top view, into a third region and a fourth region along a first straight line that passes through a light axis of the first microlens, the first region overlaps with less than 40% of the third region and 70% or more of the fourth region,
wherein in the case where the second pixel is divided, in the top view, into a fifth region and a sixth region along a second straight line that passes through a light axis of the second microlens, the second region overlaps with 70% or more of the fifth region and less than 40% of the sixth region,
wherein the first straight line is parallel to the second straight line, and
wherein a direction perpendicular to the first straight line and the second straight line is an x axis in the top view, the fourth region is positioned in a region that has a larger x-coordinate than the third region, and the sixth region is positioned in a region that has a larger x-coordinate than the fifth region.

6. The imaging device according to claim 4, comprising:
a microlens array comprising m microlenses (m is a natural number of (n−1) or less),
wherein a first microlens overlaps with the first pixel, the second pixel, the third pixel, and a fourth pixel, and
wherein a second microlens overlaps with a fifth pixel, a sixth pixel, a seventh pixel, and an eighth pixel.

7. The imaging device according to claim 6,
wherein the light-blocking layer includes a first opening,
wherein the first opening overlaps with the fifth pixel, the sixth pixel, the seventh pixel, and the eighth pixel, and
wherein the transparent conductive layer includes a region overlapping with the first opening.

8. The imaging device according to claim 6,
wherein a color filter with any of colors of red, green, and blue is provided over each of the third pixel to the n-th pixel,
wherein color filters with the same color are provided over the first pixel, the second pixel, the third pixel, and the fourth pixel, and
wherein color filters with the same color are provided over the fifth pixel, the sixth pixel, the seventh pixel, and the eighth pixel.

9. The imaging device according to claim 1,
wherein each of the n pixels includes a transistor, and
wherein the light-blocking layer overlaps with one or more of the transistors included in the third pixel to the n-th pixel.

10. The imaging device according to claim 1,
wherein each of the n pixels includes a transistor including an oxide semiconductor in a channel formation region.

11. The imaging device according to claim 1,
wherein the photoelectric conversion device is a pn-junction diode provided on a silicon substrate.

12. An imaging device comprising:
a pixel array including two or more pixels; and
a liquid crystal element positioned over the pixel array,
wherein each of the pixels included in the pixel array includes a photoelectric conversion device,
wherein the liquid crystal element includes a first region overlapping with a first pixel and a second region overlapping with a second pixel,
wherein first light enters the photoelectric conversion device included in the first pixel,
wherein second light enters the photoelectric conversion device included in the second pixel, and
wherein the imaging device is configured to sense a focal point in image formation with use of a first electric signal generated by conversion of the first light and a second electric signal generated by conversion of the second light.

13. The imaging device according to claim 12,
wherein the liquid crystal element is configured to block light when the focal point sensing is performed and transmitting light when the focal point sensing is not performed.

14. An electronic device comprising:
the imaging device according to claim 1; and
a display portion.

15. A moving object comprising:
the imaging device according to claim 1; and
an integrated circuit configured to perform image processing.

16. An electronic device comprising:
the imaging device according to claim 13; and
a display portion.

17. A moving object comprising:
the imaging device according to claim 13; and
an integrated circuit configured to perform image processing.
